(19) United States
(12) Patent Application Publication
(10) Pub. No.: US 2025/0234651 A1
(43) Pub. Date: Jul. 17, 2025

(54) ARRAY SUBSTRATE AND DISPLAY APPARATUS

(71) Applicant: BOE Technology Group Co., Ltd., Beijing (CN)

(72) Inventors: Dongfang Wang, Beijing (CN); Ce Ning, Beijing (CN); Hehe Hu, Beijing (CN); Lizhong Wang, Beijing (CN); Fengjuan Liu, Beijing (CN); Wei Liu, Beijing (CN)

(73) Assignee: BOE Technology Group Co., Ltd., Beijing (CN)

(21) Appl. No.: 18/690,592

(22) PCT Filed: May 30, 2023
(86) PCT No.: PCT/CN2023/097164

§ 371 Date: Mar. 8, 2024

(51) Int. Cl. H10D 86/40; H10D 86/60

(52) U.S. Cl. CPC H10D 86/443; H10D 86/60

(57) ABSTRACT

An array substrate includes a base substrate; a signal line on the base substrate; a buffer layer on a side of the signal line away from the base substrate; and an active layer on a side of the buffer layer away from the base substrate. The active layer includes a first electrode region, a second electrode region, and a channel region between the first electrode region and the second electrode region. The first electrode region includes a first electrode. The second electrode region includes a second electrode. The first electrode extends through a via extending at least through the buffer layer to connect to the signal line. The second electrode and at least a portion of the first electrode include a same material as the channel region. The channel region bas a conductivity different from a conductivity of the first electrode and different from a conductivity of the second electrode.

### TECHNICAL FIELD

The present invention relates to display technology, more particularly, to an array substrate and a display apparatus.

### BACKGROUND

Liquid crystal display panel has found a wide variety of applications. Typically, a liquid crystal display panel includes a counter substrate and an array substrate facing each other. Thin film transistors, gate lines, data lines, pixel electrodes, common electrodes, and common electrode signal lines are disposed on the array substrate and counter substrate. Between the two substrates, a liquid crystal material is injected to form a liquid crystal layer. One common problem associated with the liquid crystal display panel is light leakage. To prevent light leakage, a black matrix is placed on the counter substrate. A liquid crystal display panel having a larger black matrix can better prevent light leakage. However, an aperture ratio of the liquid crystal display apparatus is reduced by using a black matrix with a larger area.

Organic Light Emitting Diode (OLED) display is driven by a driving current required to be kept constant to control illumination. The OLED display panel includes a plurality of pixel units configured with pixel-driving circuits arranged in multiple rows and columns. Each pixel-driving circuit includes a driving transistor having a gate terminal connected to one gate line per row and a drain terminal connected to one data line per column. When the row in which the pixel unit is gated is turned on, the switching transistor connected to the driving transistor is turned on, and the data voltage is applied from the data line to the driving transistor via the switching transistor, so that the driving transistor outputs a current corresponding to the data voltage to an OLED device. The OLED device is driven to emit light of a corresponding brightness.

### SUMMARY

In one aspect, the present disclosure provides an array substrate, comprising a base substrate; a signal line on the base substrate; a buffer layer on a side of the signal line away from the base substrate; and an active layer on a side of the buffer layer away from the base substrate; the active layer comprises a first electrode region, a second electrode region and a channel region between the first electrode region and the second electrode region; the first electrode region comprising a first electrode, and the second electrode region comprising a second electrode; wherein the first electrode extends through a via extending at least through the buffer layer to connect to the signal line; the second electrode and at least a portion of the first electrode comprise a same material as the channel region; and the channel region has a conductivity different from a conductivity of the first electrode and different from a conductivity of the second electrode.

Optionally, materials of the channel region, the second electrode, and at least a portion of the first electrode comprise M1OₐN_{b}, wherein M1 is a single metal or a combination of metals, a>0, and b≥0), O standing for oxygen element, N standing for nitrogen element.

Optionally, the channel region, the second electrode, and at least a portion of the first electrode are parts of a unitary structure.

Optionally, the channel region, the first electrode, and the second electrode are parts of a unitary structure, and comprise M1OₐN_{b}, wherein M1 is a single metal or a combination of metals, a>0, and b≥0, O standing for oxygen element, N standing for nitrogen element.

Optionally, the first electrode comprises a first electrode part and a second electrode part electrically connected together, and the first electrode part and the second electrode part are made of different materials.

Optionally, a material of the first electrode part comprises M1OₐN_{b}, wherein M1 is a single metal or a combination of metals, a>0, and b≥0, O standing for oxygen element, N standing for nitrogen element; the second electrode part comprises a metallic material; and the first electrode part, the second electrode, and the channel region are parts of a unitary structure.

Optionally, the second electrode part is at least partially in the via; and an orthographic projection of the second electrode part on the base substrate at least partially overlaps with an orthographic projection of the signal line on the base substrate, and at least partially overlaps with an orthographic projection of the first electrode part on the base substrate.

Optionally, the orthographic projection of the first electrode part on the base substrate is non-overlapping with the orthographic projection of the signal line on the base substrate.

Optionally, the orthographic projection of the first electrode part on the base substrate partially overlaps with the orthographic projection of the signal line on the base substrate.

Optionally, the first electrode part at least partially extends into the second electrode part.

Optionally, the array substrate further comprises an insulating layer on a side of the channel region, the first electrode part, and the second electrode away from the base substrate; and a gate electrode on a side of the insulating layer away from the base substrate; wherein the second electrode part and the gate electrode are in a same layer and comprise a same electrode material.

Optionally, in a cross-section along a plane perpendicular to the base substrate and perpendicular to a length direction along which the signal line extends, and intersecting the signal line and the via, surfaces of the signal line other than a bottom surface are exposed in the via; and the bottom surface is a surface of the signal line in contact with the base substrate.

Optionally, in the cross-section, an upper surface of the signal line, and two lateral surfaces respectively connecting the upper surface to the bottom surface of the signal line, are fully covered by the first electrode.

Optionally, in the cross-section, an upper surface of only a portion of the signal line; and only one of two lateral surfaces respectively connecting the upper surface to the bottom surface of the signal line, are covered by the first electrode.

Optionally, in a cross-section along a plane perpendicular to the base substrate and perpendicular to a length direction along which the signal line extends, and intersecting the signal line and the via, at least a portion of an upper surface of the signal line, and at least one of two lateral surfaces respectively connecting the upper surface to a bottom surface of the signal line, are unexposed by the via; and the bottom surface is a surface of the signal line in contact with the base substrate.

Optionally, in the cross-section, an upper surface of only a portion of the signal line, and at least one of two lateral surfaces respectively connecting the upper surface to the bottom surface of the signal line, are covered by the buffer layer.

Optionally, in the cross-section, an upper surface of only a portion of the signal line, and only one of two lateral surfaces respectively connecting the upper surface to the bottom surface of the signal line, are covered by the first electrode.

Optionally, in the cross-section, an upper surface of only a central portion of the signal line is covered by the first electrode; and two lateral surfaces respectively connecting the upper surface to the bottom surface of the signal line are covered by the buffer layer.

Optionally, the signal line is a data line configured to provide a data signal to the first electrode.

Optionally, the active layer comprises a metal oxide material having a Hall mobility equal to or greater than 30 cm²/V·s.

Optionally, the array substrate further comprises a light shield on the base substrate and a gate line on a side of the light shield away from the base substrate; wherein the light shield is in a same layer as the signal line; and a ratio between a line width of the gate line along an extension direction of the signal line and a line width of the light shield along the extension direction of the signal line is in a range of 0.3 to 0.9.

In another aspect, the present disclosure provides a display apparatus, comprising the array substrate described herein, and one or more integrated circuits connected to the array substrate.

### BRIEF DESCRIPTION OF THE FIGURES

The following drawings are merely examples for illustrative purposes according to various disclosed embodiments and are not intended to limit the scope of the present invention.

FIG. 1A is a plan view of an array substrate in some embodiments according to the present disclosure.

FIG. 1B is a plan view of an array substrate in some embodiments according to the present disclosure.

FIG. 1C is a plan view of an array substrate in some embodiments according to the present disclosure.

FIG. 1D is a plan view of an array substrate in some embodiments according to the present disclosure.

FIG. 1E is a plan view of an array substrate in some embodiments according to the present disclosure.

FIG. 2A is a cross-sectional view of an array substrate in some embodiments according to the present disclosure.

FIG. 2B is a cross-sectional view of an array substrate in some embodiments according to the present disclosure.

FIG. 3A is a plan view of an array substrate in some embodiments according to the present disclosure.

FIG. 3B is a plan view of an array substrate in some embodiments according to the present disclosure.

FIG. 4 is a cross-sectional view of an array substrate in some embodiments according to the present disclosure.

FIG. 5 is a plan view of an array substrate in some embodiments according to the present disclosure.

FIG. 6 is a cross-sectional view of an array substrate in some embodiments according to the present disclosure.

FIG. 7 is a plan view of an array substrate in some embodiments according to the present disclosure.

FIG. 8 is a cross-sectional view of an array substrate in some embodiments according to the present disclosure.

FIG. 9A is a cross-sectional view of an array substrate in some embodiments according to the present disclosure.

FIG. 9B is a cross-sectional view of an array substrate in some embodiments according to the present disclosure.

FIG. 10 is a cross-sectional view of an array substrate in some embodiments according to the present disclosure.

FIG. 11 is a cross-sectional view of an array substrate in some embodiments according to the present disclosure.

FIG. 12 is a cross-sectional view of an array substrate in some embodiments according to the present disclosure.

FIG. 13A is a plan view of an array substrate in some embodiments according to the present disclosure.

FIG. 13B is a plan view of an array substrate in some embodiments according to the present disclosure.

FIG. 14 is a cross-sectional view of an array substrate in some embodiments according to the present disclosure.

FIG. 15 is a schematic diagram illustrating the structure of a first electrode of the array substrate depicted in FIG. 14.

FIG. 16A is a plan view of an array substrate in some embodiments according to the present disclosure.

FIG. 16B is a plan view of an array substrate in some embodiments according to the present disclosure.

FIG. 17 is a cross-sectional view of an array substrate in some embodiments according to the present disclosure.

FIG. 18 is a schematic diagram illustrating the structure of a first electrode of the array substrate depicted in FIG. 17.

FIG. 19 is a plan view of an array substrate in some embodiments according to the present disclosure.

FIG. 20 is a cross-sectional view of an array substrate in some embodiments according to the present disclosure.

FIG. 21 is a schematic diagram illustrating the structure of a first electrode of the array substrate depicted in FIG. 20.

FIG. 22A is a plan view of an array substrate in some embodiments according to the present disclosure.

FIG. 22B is a plan view of an array substrate in some embodiments according to the present disclosure.

FIG. 23 is a cross-sectional view of an array substrate in some embodiments according to the present disclosure.

FIG. 24 is a schematic diagram illustrating the structure of a first electrode of the array substrate depicted in FIG. 23.

FIG. 25A to FIG. 25H illustrate various arrangements of a second electrode part with respect to adjacent components in an array substrate in some embodiments according to the present disclosure.

FIG. 26A to FIG. 26C illustrate a process of fabricating an array substrate in some embodiments according to the present disclosure.

FIG. 27A to FIG. 27C illustrate a process of fabricating an array substrate in some embodiments according to the present disclosure.

FIG. 28A to FIG. 28B illustrate a process of fabricating an array substrate in some embodiments according to the present disclosure.

FIG. 29A to FIG. 29C illustrate a process of fabricating an array substrate in some embodiments according to the present disclosure.

FIG. 30A to FIG. 30C illustrate a process of fabricating an array substrate in some embodiments according to the present disclosure.

FIG. 31A to FIG. 31B illustrate a process of fabricating an array substrate in some embodiments according to the present disclosure.

FIG. 32A to FIG. 32C illustrate a process of fabricating an array substrate in some embodiments according to the present disclosure.

FIG. 33A to FIG. 33C illustrate a process of fabricating an array substrate in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, an array substrate and a display apparatus that substantially obviate one or more of the problems due to limitations and disadvantages of the related art. In one aspect, the array substrate comprises a base substrate; a signal line on the base substrate; a buffer layer on a side of the signal line away from the base substrate; and an active layer on a side of the buffer layer away from the base substrate; the active layer comprises a first electrode region, a second electrode region, and a channel region between the first electrode region and the second electrode region; the first electrode region comprising a first electrode, and the second electrode region comprising a second electrode. Optionally, the first electrode extends through a via extending at least through the buffer layer to connect to the signal line. Optionally, the second electrode and at least a portion of the first electrode comprise a same material as the channel region. Optionally, the channel region has a conductivity different from a conductivity of the first electrode and different from a conductivity of the second electrode.

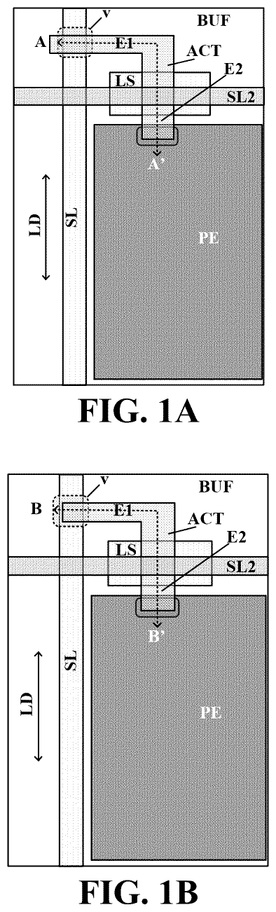

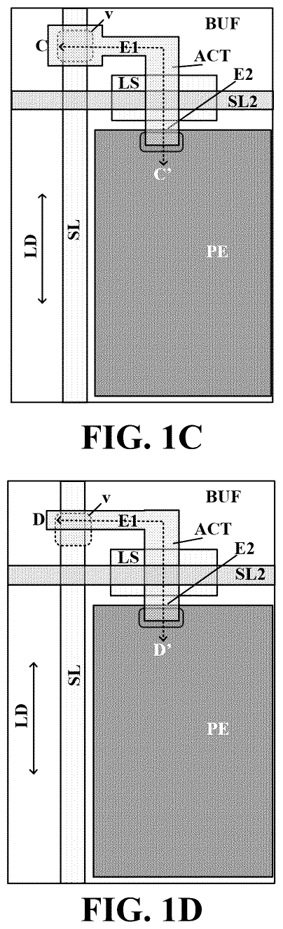

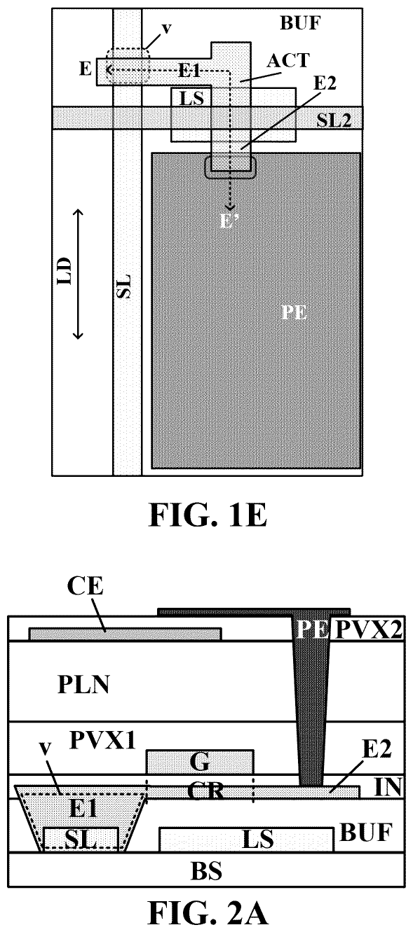

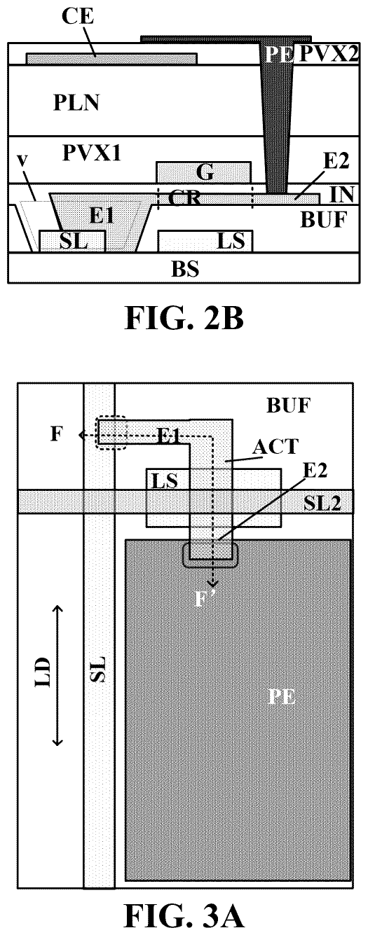

FIG. 1A is a plan view of an array substrate in some embodiments according to the present disclosure. FIG. 2A is a cross-sectional view of an array substrate in some embodiments according to the present disclosure. FIG. 2A may be a cross-sectional view along an A-A′ line in FIG. 1A. Referring to FIG. 1A and FIG. 2A, the array substrate in some embodiments includes a base substrate BS; a signal line SL (e.g., a data line configured to provide a data signal to a transistor) on the base substrate BS; a buffer layer BUF on a side of the signal line SL away from the base substrate BS; an active layer ACT on a side of the buffer layer BUF away from the base substrate BS. The active layer ACT includes a first electrode region, a second electrode region, and a channel region CR between the first electrode region and the second electrode region. The first electrode region includes a first electrode E1, and the second electrode region includes a second electrode E2. The array substrate in some embodiments further includes an insulating layer IN (e.g., a gate insulating layer) on a side of the active layer ACT (e.g., on a side of the first electrode E1, the channel region CR, and the second electrode E2) away from the buffer layer BUF.

In some embodiments, the array substrate further includes a gate electrode G on a side of the insulating layer IN away from the channel region CR. The gate electrode G defines the area of the channel region CR. For example, an orthographic projection of the gate electrode G on the base substrate substantially overlaps with an orthographic projection of the channel region CR on the base substrate BS.

In some embodiments, the array substrate further includes a light shield LS on the base substrate BS. Optionally, the light shield LS is in a same layer as the signal line SL, e.g., formed in a same patterning process using a same mask plate, and/or using a same material. The light shield LS is configured to prevent light from irradiating on the channel region CR. Optionally, an orthographic projection of the light shield LS on the base substrate BS is at least partially (e.g., at least 50%, at least 60%, at least 70%, at least 80%, at least 90%, at least 95%, at least 98%, at least 99%, or 100%) overlaps with an orthographic projection of the channel region CR on the base substrate BS.

In some embodiments, the array substrate further includes a first passivation layer PVX1 on a side of the gate electrode G away from the base substrate BS; a planarization layer PLN on a side of the first passivation layer PVX1 away from the base substrate BS; a second passivation layer PVX2 on a side of the planarization layer PLN away from the first passivation layer PVX1; and a pixel electrode PE on a side of the second passivation layer PVX2 away from the planarization layer PLN. The pixel electrode PE optionally extends through at least the second passivation layer PVX2, the planarization layer PLN, and the first passivation layer PVX1, to connect to the second electrode E2. Optionally, as shown in FIG. 2A, the pixel electrode PE further extends through the insulating layer IN. The arrays substrate includes a via extending through the second passivation layer PVX2, the planarization layer PLN, the first passivation layer PVX1, and the insulating layer IN, as shown in FIG. 2A.

In some embodiments, the array substrate further includes a common electrode CE on a side of the planarization layer PLN away from the first passivation layer PVX1. Optionally, the common electrode CE is on a side of the second passivation layer PVX2 closer to the planarization layer PLN.

The present array substrate may be implemented in various appropriate display panels. Appropriate array substrates include a liquid crystal display array substrate, an organic light emitting diode array substrate, a micro light emitting diode array substrate, and a mini light emitting diode array substrate.

In some embodiments, the array substrate is a liquid crystal display array substrate. The pixel electrode PE is a pixel electrode in a respective subpixel of a plurality of subpixels in the liquid crystal display array substrate. The common electrode CE is a common electrode in the liquid crystal display array substrate. In one example, the common electrode CE is an electrode extending throughout the plurality of subpixels in the liquid crystal display array substrate.

In some embodiments, the array substrate is a light emitting diode display array substrate. The pixel electrode PE is an anode of a respective light emitting diode of a plurality of light emitting diodes in the light emitting diode display array substrate. The common electrode CE is a cathode in the light emitting diode display array substrate. In one example, the common electrode is a cathode extending throughout a plurality of subpixels in the light emitting diode display array substrate. In another example, the common electrode CE is on a side of a light emitting layer and the pixel electrode PE away from the base substrate BS.

Various appropriate semiconductor materials and various appropriate fabricating methods may be used to make the channel region CR. In some embodiments, the semiconductor material includes M1OₐN_{b}, wherein M1 is a single metal or a combination of metals, a>0, and b≥0, O standing for oxygen element, N standing for nitrogen element, e.g., the semiconductor material is a metal oxide material or a metal oxynitride material. Examples of appropriate metal oxide materials include, but are not limited to, indium gallium zinc oxide, zinc oxide, gallium oxide, indium oxide, HfInZnO) (HIZO), amorphous InGaZnO (amorphous IGZO), InZnO, amorphous InZnO, ZnO:F, In2O3:Sn, In2O3:Mo, Cd2SnO4, ZnO:Al, TiO2:Nb, and Cd—Sn—O. Examples of appropriate metal oxynitride materials include, but are not limited to, zinc oxynitride, indium oxynitride, gallium oxynitride, tin oxynitride, cadmium oxynitride, aluminum oxynitride, germanium oxynitride, titanium oxynitride, silicon oxynitride, or combination thereof. In one example, the channel region CR includes indium gallium zine oxide.

Various appropriate conductive materials and various appropriate fabricating methods may be used to make the first electrode E1 or the second electrode E2. Examples of appropriate conductive materials include a metal, an alloy, a metal oxide, and any combination thereof. Examples of appropriate conductive materials for making the first electrode El or the second electrode E2 include, but are not limited to, molybdenum, aluminum, titanium, gold, copper, hafnium, tantalum, alloys such as aluminum Neodymium (AlNd), molybdenum Niobium (MoNb), and laminates such as a molybdenum-neodymium-copper laminated structure, a molybdenum-niobium-titanium (MTD) laminated structure, a molybdenum-nickel-titanium-copper laminated structure, a molybdenum-nickel-titanium-copper-molybdenum-nickel-titanium laminated structure, a molybdenum-neodymium-copper laminated structure, a molybdenum-aluminum-aluminum laminated structure, molybdenum-aluminum-molybdenum laminated structure, a MoNb-copper-MoNb laminated structure, and a AlNd-molybdenum-AlNd laminated structure.

In some embodiments, the conductive material for making the first electrode E1 or the second electrode E2 includes M1OₐN_{b}, wherein M1 is a single metal or a combination of metals, a>0, and b≥0, O standing for oxygen element, N standing for nitrogen element, e.g., the conductive material is a metal oxide material or a metal oxynitride material. Examples of appropriate metal oxide materials include, but are not limited to, indium gallium zinc oxide, zinc oxide, gallium oxide, indium oxide, HfInZnO (HIZO), InGaZnO (IGZO), crystalline, InZnO, amorphous InZnO, ZnO:F, In2O3:Sn, In2O3:Mo, Cd2SnO4, ZnO:Al, TiO2:Nb, Cd—Sn—O, InGaO(IGO), InGaZnSnO(IGZTO), Lanthanide doped oxide semiconductor (Ln-OS). The crystallinity can be amorphous, partially crystalline, or crystalline. Examples of appropriate metal oxynitride materials include, but are not limited to, zinc oxynitride, indium oxynitride, gallium oxynitride, tin oxynitride, cadmium oxynitride, aluminum oxynitride, germanium oxynitride, titanium oxynitride, silicon oxynitride, or combination thereof. In one example, the first electrode E1 or the second electrode E2 includes indium gallium zinc oxide.

In some embodiments, when a material of the channel region CR, the first electrode E1 or the second electrode E2 include M1OₐN_{b}, the first electrode E1 or the second electrode E2 differs from the channel region CR in that the first electrode E1 or the second electrode E2 is subject to a process to make it more conductive. The channel region CR has a conductivity different from a conductivity of the first electrode E1 and different from a conductivity of the second electrode E2. In one example, when a material of the channel region CR, the first electrode E1 or the second electrode E2 include M1OₐN_{b}, the M1OₐN_{b} in the first electrode E1 or the second electrode E2 is subject to a lightly doped drain process (e.g., a lightly-doping ion implantation process). In another example, when a material of the channel region CR, the first electrode E1 or the second electrode E2 include M1OₐN_{b}, the M1OₐN_{b} in the first electrode E1 of the second electrode E2 is subject to an annealing process. In another example, when a material of the channel region CR, the first electrode E1 or the second electrode E2 include M1OₐN_{b}, the M1OₐN_{b} in the first electrode E1 or the second electrode E2 is subject to an oxide supplementation process. Optionally, the lightly doped drain process is performed using a doping concentration in a range of approximately 1×10¹⁵ atoms/cm³ to approximately 1×10²⁰ atoms/cm³, e.g., approximately 1×10¹⁵ atoms/cm³ to approximately 1×10¹⁶ atoms/cm³, approximately 1×10¹⁶ atoms/cm³ to approximately 1×10¹⁷ atoms/cm³, approximately 1×10¹⁷ atoms/cm³ to approximately 1×10¹⁸ atoms/cm³, approximately 1×10¹⁸ atoms/cm³ to approximately 1×10²⁰ atoms/cm³, and approximately 1×10¹⁹ atoms/cm³ to approximately 1×10²⁰ atoms/cm³. Optionally, the lightly doped drain process is performed using an n-type dopant for enhancing conductivity. Examples of n-type dopants include a Group VA element of the Periodic Table of the Elements including nitrogen (N), phosphorous (P), arsenic (As), antimony (Sb), and bismuth (Bi).

In some embodiments, a material of the channel region CR, the first electrode E1, and the second electrode E2 include M1OₐN_{b}. The channel region CR, the first electrode E1, and the second electrode E2 are parts of a unitary structure, as shown in FIG. 1A and FIG. 2A.

In some embodiments, the active layer ACT includes a metal oxide material having a Hall mobility equal to or greater than 30 cm²/V·s.

In some embodiments, the array substrate includes a via v extending through at least the buffer layer BUF. The first electrode E1 at least partially in the via v. Optionally, the first electrode E1 extends through the via v to connect to the signal line SL.

In some embodiments, referring to FIG. 1A and FIG. 2A, in a cross-section along a plane perpendicular to the base substrate BS and perpendicular to a length direction LD along which the signal line SL extends, and intersecting the signal line and the via v (e.g., the cross-section as shown in FIG. 2A), surfaces of the signal line SL other than a surface in contact with the base substrate BS are exposed in the via v. For example, in the cross-section, an upper surface of the signal line SL, and two lateral surfaces respectively connecting the upper surface to a bottom surface of the signal line SL, are fully exposed in the via v. The bottom surface is a surface of the signal line SL in contact with the base substrate BS.

In some embodiments, referring to FIG. 1A and FIG. 2A, in a cross-section along a plane perpendicular to the base substrate BS and perpendicular to a length direction LD along which the signal line SL extends, and intersecting the signal line and the via y (e.g., the cross-section as shown in FIG. 2A), surfaces of the signal line SL other than a surface in contact with the base substrate BS are covered by the first electrode E1. For example, in the cross-section, an upper surface of the signal line SL, and two lateral surfaces respectively connecting the upper surface to a bottom surface of the signal line SL, are fully covered by the first electrode E1. The bottom surface is a surface of the signal line SL in contact with the base substrate BS.

As used herein, the terms “overlap” and “cover” refer to the spatial positional relationship between the layers themselves, alternatively refer to the positional relationship between the orthographic projections of the layers on the base substrate.

In some embodiments, referring to FIG. 1A, the first electrode E1 crosses over the signal line SL. An orthographic projection of the first electrode E1 on the base substrate crosses over an orthographic projection of the signal line SL on the base substrate.

FIG. 1B is a plan view of an array substrate in some embodiments according to the present disclosure. FIG. 2B is a cross-sectional view of an array substrate in some embodiments according to the present disclosure. FIG. 2B may be a cross-sectional view along a B-B′ line in FIG. 1B. Referring to FIG. 1B and FIG. 2B, in some embodiments, the array substrate includes a via v extending through at least the buffer layer BUF. The first electrode E1 at least partially in the via v. Optionally, the first electrode E1 extends through the via v to connect to the signal line SL.

In some embodiments, referring to FIG. 1B and FIG. 2B, in a cross-section along a plane perpendicular to the base substrate BS and perpendicular to a length direction LD along which the signal line SL extends, and intersecting the signal line SL and the via v (e.g., the cross-section as shown in FIG. 2B), surfaces of the signal line SL other than a surface in contact with the base substrate BS are exposed in the via v. For example, in the cross-section, an upper surface of the signal line SL, and two lateral surfaces respectively connecting the upper surface to a bottom surface of the signal line SL, are fully exposed in the via v. The bottom surface is a surface of the signal line in contact with the base substrate BS.

In some embodiments, referring to FIG. 1B and FIG. 2B, in a cross-section along a plane perpendicular to the base substrate BS and perpendicular to a length direction LD along which the signal line SL extends, and intersecting the signal line SL and the via v (e.g., the cross-section as shown in FIG. 2B), surfaces of the signal line SL other than a surface in contact with the base substrate BS are exposed in the via v. For example, in the cross-section, an upper surface of the signal line SL, and two lateral surfaces respectively connecting the upper surface to a bottom surface of the signal line SL, are fully exposed in the via v. The bottom surface is a surface of the signal line SL in contact with the base substrate BS.

In some embodiments, referring to FIG. 1B and FIG. 2B, in a cross-section along a plane perpendicular to the base substrate BS and perpendicular to a length direction LD along which the signal line SL extends, and intersecting the signal line SL and the via v (e.g., the cross-section as shown in FIG. 2B), surfaces of the signal line SL other than a surface in contact with the base substrate BS are only partially covered by the first electrode E1. For example, in the cross-section, an upper surface of only a portion of the signal line SL, and only one of two lateral surfaces respectively connecting the upper surface to a bottom surface of the signal line SL, are covered by the first electrode E1. The bottom surface is a surface of the signal line SL in contact with the base substrate BS.

In some embodiments, referring to FIG. 1B, the first electrode E1 only partially crosses over the signal line SL. An orthographic projection of the first electrode E1 on the base substrate only partially crosses over an orthographic projection of the signal line SL on the base substrate.

Referring to FIG. 1A and FIG. 1B, in some embodiments, an orthographic projection of the first electrode E1 on the base substrate only partially overlaps with an orthographic projection of the via v on the base substrate.

FIG. 1C is a plan view of an array substrate in some embodiments according to the present disclosure. FIG. 2A may be a cross-sectional view along a C-C′ line in FIG. 1C. Referring to FIG. 1C and FIG. 2A, in some embodiments, an orthographic projection of the first electrode E1 on the base substrate completely covers an orthographic projection of the via v on the base substrate.

Referring to FIG. 1A, in some embodiments, an orthographic projection of the first electrode E1 on the base substrate overlaps with an orthographic projection of a middle portion of the via v on the base substrate, is non-overlapping with an orthographic projection of an upper portion of the via v on the base substrate, and is non-overlapping with an orthographic projection of a lower portion of the via v on the base substrate. The upper portion, the middle portion, and the lower portion are sequentially arranged along the length direction of the signal line SL.

FIG. 1D is a plan view of an array substrate in some embodiments according to the present disclosure. FIG. 2A may be a cross-sectional view along a D-D′ line in FIG. 1D. Referring to FIG. 1D and FIG. 2A, in some embodiments, an orthographic projection of the first electrode E1 on the base substrate overlaps with an orthographic projection of an upper portion of the via v on the base substrate, and is non-overlapping with an orthographic projection of a lower portion of the via v on the base substrate. The upper portion and the lower portion are sequentially arranged along the length direction of the signal line SL.

FIG. 1E is a plan view of an array substrate in some embodiments according to the present disclosure. FIG. 2A may be a cross-sectional view along a E-E′ line in FIG. 1E. Referring to FIG. 1E and FIG. 2A, in some embodiments, an orthographic projection of the first electrode E1 on the base substrate overlaps with an orthographic projection of a lower portion of the via v on the base substrate, and is non-overlapping with an orthographic projection of an upper portion of the via v on the base substrate. The upper portion and the lower portion are sequentially arranged along the length direction of the signal line SL.

Referring to FIG. 1A to FIG. 1E, the array substrate in some embodiments further includes a second signal line SL2. In some embodiments, the second signal line SL2 is a gate line configured to provide a gate driving signal to the transistor. In some embodiments, the gate electrode is a portion of the gate line GL. An orthographic projection of the channel region CR on the base substrate overlaps with an orthographic projection the gate electrode on the base substrate.

In some embodiments, the array substrate includes a light shield LS on the base substrate and a gate line (e.g., the second signal line SL2) on a side of the light shield LS away from the base substrate. The light shield LS is in a same layer as the signal line SL. Optionally, a ratio between a line width of the gate line along an extension direction of the signal line and a line width of the light shield along the extension direction of the signal line is in a range of 0.3 to 0.9, e.g., 0.3 to 0.4, 0.4 to 0.5, 0.5 to 0.6, 0.6 to 0.7, 0.7 to 0.8, or 0.8 to 0.9. The inventors of the present disclosure discover that, by having this layout, it can ensure light shielding, preserve aperture ratio in the array substrate, and avoid short circuit between the gate line and the light shield LS.

As used herein, the term “same layer” refers to the relationship between the layers simultaneously formed in the same step. In one example, the light shield LS and the signal line SL are in a same layer when they are formed as a result of one or more steps of a same patterning process performed in a material deposited in a same deposition process. In another example, the light shield LS and the signal line SL can be formed in a same layer by simultaneously performing the step of forming the light shield LS and the step of forming the signal line SL. The term “same layer” does not always mean that the thickness of the layer of the height of the layer in a cross-sectional view is the same.

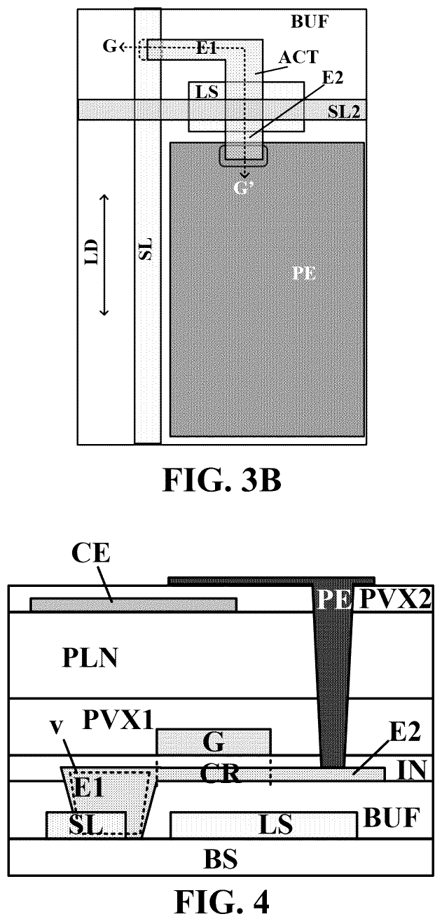

FIG. 3A is a plan view of an array substrate in some embodiments according to the present disclosure. FIG. 3B is a plan view of an array substrate in some embodiments according to the present disclosure. FIG. 4 is a cross-sectional view of an array substrate in some embodiments according to the present disclosure, FIG. 4 may be a cross-sectional view along an F-F′ line in FIG. 3A, or along a G-G′ line in FIG. 3B. Referring to FIG. 3A, FIG. 3B, and FIG. 4, in some embodiments, in a cross-section along a plane perpendicular to the base substrate BS and perpendicular to a length direction LD along which the signal line SL extends, and intersecting the signal line SL and the via v (e.g., the cross-section as shown in FIG. 4), at least a portion of the signal line SL is covered by the buffer layer BUF, and at least a portion of an upper surface of the signal line SL are unexposed by the via v. For example, in the cross-section, a first portion of the signal line SL is covered by the buffer layer BUF, and a second portion of the signal line SL are not covered the buffer layer BUF. In the cross-section, an upper surface of the first portion of the signal line SL is unexposed by the via v, and an upper surface of the second portion of the signal line SL is exposed by the via v. The first portion is on a side of the second portion away from the channel region CR.

In some embodiments, referring to FIG. 3A, FIG. 3B, and FIG. 4, in a cross-section along a plane perpendicular to the base substrate BS and perpendicular to a length direction LD along which the signal line SL extends, and intersecting the signal line SL and the via v (e.g., the cross-section as shown in FIG. 4), surfaces of the signal line SL other than a surface in contact with the base substrate BS are only partially covered by the first electrode E1. For example, in the cross-section, an upper surface of only a portion of the signal line SL, and only one of two lateral surfaces respectively connecting the upper surface to a bottom surface of the signal line SL, are covered by the first electrode E1. The bottom surface is a surface of the signal line SL in contact with the base substrate BS.

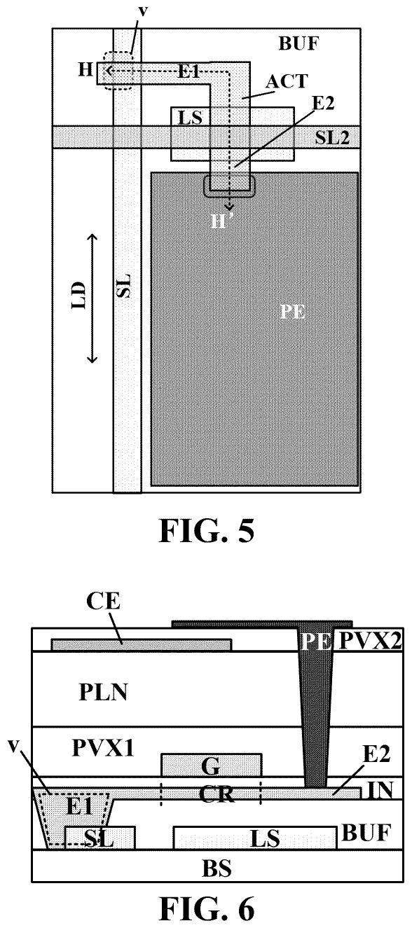

FIG. 5 is a plan view of an array substrate in some embodiments according to the present disclosure. FIG. 6 is a cross-sectional view of an array substrate in some embodiments according to the present disclosure. FIG. 6 may be a cross-sectional view along an H-H′ line in FIG. 5. Referring to FIG. 5 and FIG. 6, in some embodiments, in a cross-section along a plane perpendicular to the base substrate BS and perpendicular to a length direction LD along which the signal line SL extends, and intersecting the signal line SL and the via v (e.g., the cross-section as shown in FIG. 6), at least a portion of the signal line SL is covered by the buffer layer BUF, and at least a portion of an upper surface of the signal line SL is unexposed by the via v. For example, in the cross-section, a first portion of the signal line SL is not covered the buffer layer BUF, and a second portion of the signal line SL is covered by the buffer layer BUF. In the cross-section, an upper surface of the first portion of the signal line SL is exposed by the via v, and an upper surface of the second portion of the signal line SL is unexposed by the via v. The first portion is on a side of the second portion away from the channel region CR.

In some embodiments, referring to FIG. 5 and FIG. 6, in a cross-section along a plane perpendicular to the base substrate BS and perpendicular to a length direction LD along which the signal line SL extends, and intersecting the signal line SL and the via v (e.g., the cross-section as shown in FIG. 6), surfaces of the signal line SL other than a surface in contact with the base substrate BS are only partially covered by the first electrode E1. For example, in the cross-section, an upper surface of only a portion of the signal line SL, and only one of two lateral surfaces respectively connecting the upper surface to a bottom surface of the signal line SL, are covered by the first electrode E1. The bottom surface is a surface of the signal line SL in contact with the base substrate BS.

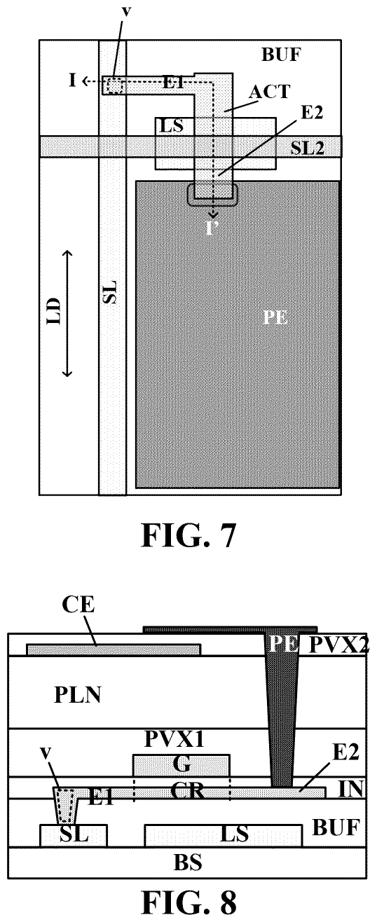

FIG. 7 is a plan view of an array substrate in some embodiments according to the present disclosure. FIG. 8 is a cross-sectional view of an array substrate in some embodiments according to the present disclosure. FIG. 8 may be a cross-sectional view along an I-I′ line in FIG. 7. Referring to FIG. 7 and FIG. 8, in some embodiments, in a cross-section along a plane perpendicular to the base substrate BS and perpendicular to a length direction LD along which the signal line SL extends, and intersecting the signal line SL and the via v (e.g., the cross-section as shown in FIG. 6), at least a portion of the signal line SL is covered by the buffer layer BUF, and at least a portion of an upper surface of the signal line SL is unexposed by the via. For example, in the cross-section, a central portion of the signal line SL is not covered the buffer layer BUF, and two side portions of the signal line SL are covered by the buffer layer BUF. In the cross-section, an upper surface of the central portion of the signal line SL is exposed by the via v, and upper surfaces of the two side portions of the signal line SL are unexposed by the via v.

In some embodiments, referring to FIG. 7 and FIG. 8, in a cross-section along a plane perpendicular to the base substrate BS and perpendicular to a length direction LD along which the signal line SL extends, and intersecting the signal line SL and the via v (e.g., the cross-section as shown in FIG. 8), only an upper surface of a portion of the signal line SL is covered by the first electrode E1. An upper surface of other portions of the signal line SL, and two lateral surfaces respectively connecting the upper surface to a bottom surface of the signal line SL, are not covered by the first electrode E1. The bottom surface is a surface of the signal line SL in contact with the base substrate BS.

In some embodiments, the insulating layer IN extends substantially throughout the array substrate, as shown in FIG. 1A to FIG. 1E, FIG. 2A, FIG. 2B, FIG. 3A, FIG. 3B, and FIG. 4 to FIG. 8.

In some embodiments, the insulating layer does not extend substantially throughout the array substrate. For example, an orthographic projection of the insulating layer on the base substrate is at least partially non-overlapping with an orthographic projection of the signal line on the base substrate, and is at least partially non-overlapping with an orthographic projection of the first electrode or the second electrode on the base substrate.

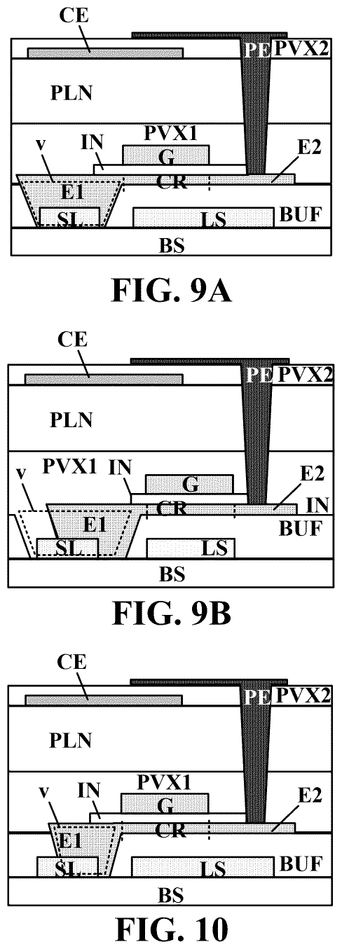

FIG. 9A is a cross-sectional view of an array substrate in some embodiments according to the present disclosure. The structure shown in FIG. 9A is similar to the structure shown in FIG. 2A, but differs from the structure shown in FIG. 2A at least in that the insulating layer IN does not extend substantially throughout the array substrate depicted in FIG. 9A.

FIG. 9B is a cross-sectional view of an array substrate in some embodiments according to the present disclosure. The structure shown in FIG. 9B is similar to the structure shown in FIG. 2B, but differs from the structure shown in FIG. 2B at least in that the insulating layer IN does not extend substantially throughout the array substrate depicted in FIG. 9B.

FIG. 10 is a cross-sectional view of an array substrate in some embodiments according to the present disclosure. The structure shown in FIG. 10 is similar to the structure shown in FIG. 4, but differs from the structure shown in FIG. 10 at least in that the insulating layer IN does not extend substantially throughout the array substrate depicted in FIG. 10.

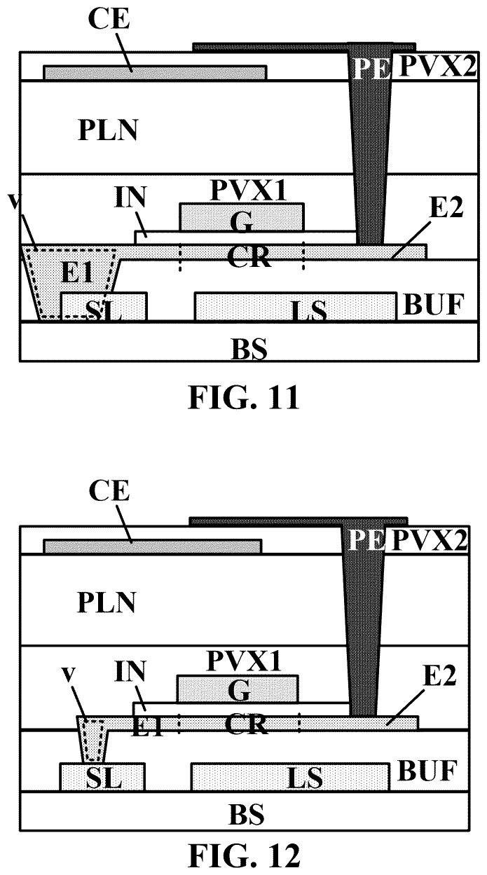

FIG. 11 is a cross-sectional view of an array substrate in some embodiments according to the present disclosure. The structure shown in FIG. 11 is similar to the structure shown in FIG. 6, but differs from the structure shown in FIG. 11 at least in that the insulating layer IN does not extend substantially throughout the array substrate depicted in FIG. 11.

FIG. 12 is a cross-sectional view of an array substrate in some embodiments according to the present disclosure. The structure shown in FIG. 12 is similar to the structure shown in FIG. 8, but differs from the structure shown in FIG. 12 at least in that the insulating layer IN does not extend substantially throughout the array substrate depicted in FIG. 12.

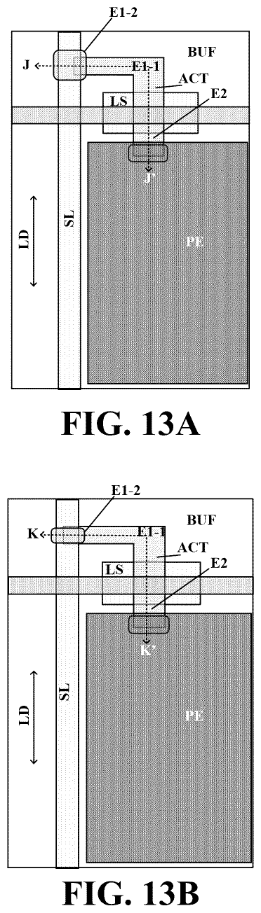

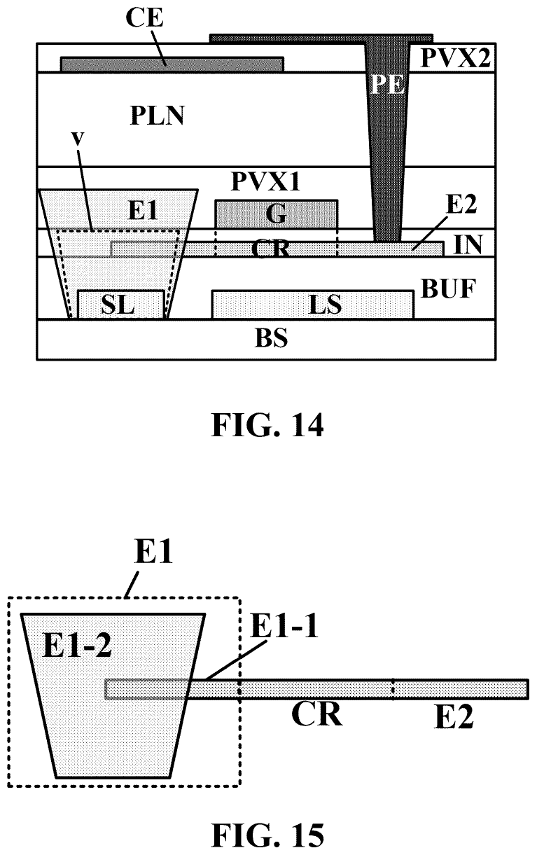

FIG. 13A is a plan view of an array substrate in some embodiments according to the present disclosure. FIG. 14 is a cross-sectional view of an array substrate in some embodiments according to the present disclosure. FIG. 15 is a schematic diagram illustrating the structure of a first electrode in the array substrate depicted in FIG. 14. FIG. 14 may be a cross-sectional view along a J-J′ line in FIG. 13A. Referring to FIG. 13A, FIG. 14, and FIG. 15, the first electrode E1 in some embodiments includes a first electrode part E1-1 and a second electrode part E1-2 electrically connected together. The first electrode part E1-1 and the second electrode part E1-2 are made of different materials. Optionally, the first electrode part E1-1 at least partially extends into the second electrode part E1-2.

Various appropriate conductive materials and various appropriate fabricating methods may be used to make the first electrode part E1-1. In some embodiments, the conductive material for making the first electrode part E1-1 includes M1OₐN_{b}, wherein M1 is a single metal or a combination of metals, a>0, and b≥0, O standing for oxygen element, N standing for nitrogen element, e.g., the conductive material is a metal oxide material or a metal oxynitride material. In some embodiments, when a material of the channel region CR, the first electrode part E1-1, and the second electrode E2 include M1OₐN_{b}, the first electrode part E1-1 or the second electrode E2 differs from the channel region CR in that the first electrode part E1-1 or the second electrode E2 is subject to a process to make it more conductive. The channel region CR has a conductivity different from a conductivity of the first electrode E1 and different from a conductivity of the second electrode E2. In one example, when a material of the channel region CR, the first electrode part E1-1 or the second electrode E2 include M1OₐN_{b}, the M1OₐN_{b} in the first electrode part E1-1 or the second electrode E2 is subject to a lightly doped drain process (e.g., a lightly-doping ion implantation process). In another example, when a material of the channel region CR, the first electrode part E1-1 or the second electrode E2 include M1OₐN_{b}, the M1OₐN_{b} in the first electrode part E1-1 or the second electrode E2 is subject to an annealing process. In another example, when a material of the channel region CR, the first electrode part E1-1 or the second electrode E2 include M1OₐN_{b}, the M1OₐN_{b} in the first electrode part E1-1 or the second electrode E2 is subject to an oxide supplementation process.

In some embodiments, a material of the channel region CR, the first electrode part E1-1, and the second electrode E2 include M1OₐN_{b}. The channel region CR, the first electrode part E1-1, and the second electrode E2 are parts of a unitary structure, as shown in FIG. 13A, FIG. 14, and FIG. 15.

Various appropriate conductive materials and various appropriate fabricating methods may be used to make the second electrode part E1-2. Examples of appropriate conductive materials include a metal, an alloy, a metal oxide, and any combination thereof. In one example, the second electrode part E1-2 includes a molybdenum-neodymium-copper laminated structure, a MTD-copper laminated structure, or a MTD-copper-MTD laminated structure.

In some embodiments, the array substrate includes a via v extending through at least the buffer layer BUF. The second electrode part E1-2 at least partially in the via v. Optionally, the second electrode part E1-2 extends through the via v to connect to the signal line SL. In one example as depicted in FIG. 14, the via v extends through the insulating layer IN and the buffer layer BUF. In another example, the second electrode part E1-2 and the gate electrode G include a same conductive material, and are formed in a same patterning process using a same mask plate.

Referring to FIG. 13A and FIG. 14, in a cross-section along a plane perpendicular to the base substrate BS and perpendicular to a length direction LD along which the signal line SL extends, and intersecting the signal line and the via v (e.g., the cross-section as shown in FIG. 14), surfaces of the signal line SL other than a surface in contact with the base substrate BS are exposed in the via v. For example, in the cross-section, an upper surface of the signal line SL, and two lateral surfaces respectively connecting the upper surface to a bottom surface of the signal line SL, are fully exposed in the via v. The bottom surface is a surface of the signal line in contact with the base substrate BS. In the cross-section, the second electrode part E1-2 covers the upper surface of the signal line SL, and covers two lateral surfaces respectively connecting the upper surface to a bottom surface of the signal line SL.

In some embodiments, referring to FIG. 13A, the second electrode part E1-2 crosses over the signal line SL. An orthographic projection of the second electrode part E1-2 on the base substrate crosses over an orthographic projection of the signal line SL on the base substrate.

In some embodiments, referring to FIG. 13A, a maximum width of the second electrode part E1-2 along the length direction LD is greater than a maximum width of the first electrode part E1-1 along the length direction LD.

FIG. 13B is a plan view of an array substrate in some embodiments according to the present disclosure. FIG. 14 may be a cross-sectional view along a K-K′ line in FIG. 13B. Referring to FIG. 13B and FIG. 14, in some embodiments, a maximum width of the second electrode part E1-2 along the length direction LD is less than or equal to a maximum width of the first electrode part E1-1 along the length direction LD.

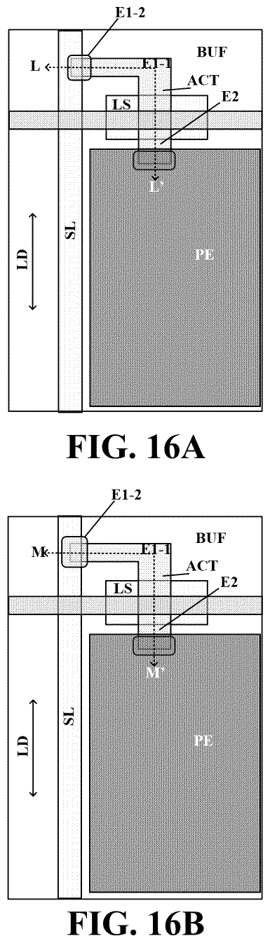

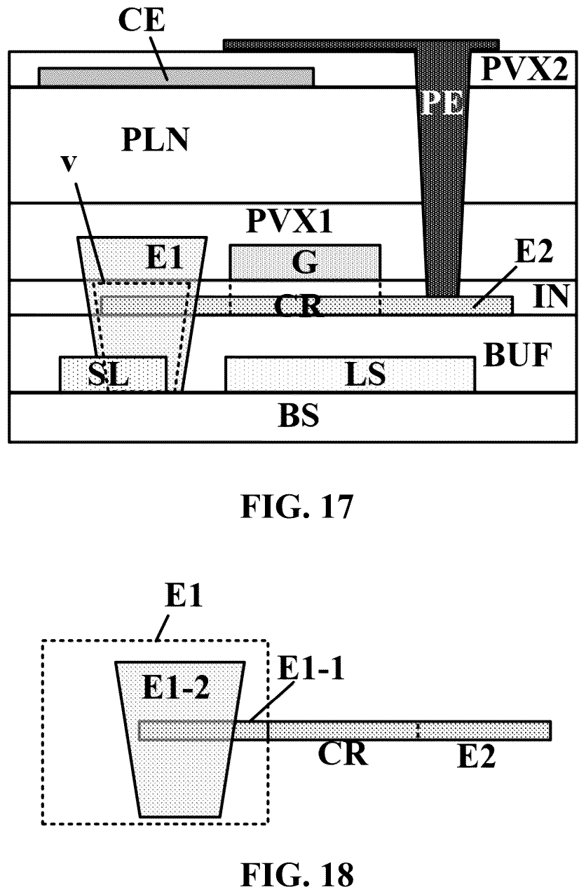

FIG. 16A is a plan view of an array substrate in some embodiments according to the present disclosure. FIG. 16B is a plan view of an array substrate in some embodiments according to the present disclosure. FIG. 17 is a cross-sectional view of an array substrate in some embodiments according to the present disclosure. FIG. 18 is a schematic diagram illustrating the structure of a first electrode of the array substrate depicted in FIG. 17. FIG. 17 may be a cross-sectional view along a L-L′ line in FIG. 16A, or along a M-M′ line in FIG. 16B. Referring to FIG. 16A, FIG. 16B, and FIG. 17, in some embodiments, in a cross-section along a plane perpendicular to the base substrate BS and perpendicular to a length direction LD along which the signal line SL extends, and intersecting the signal line SL and the via v (e.g., the cross-section as shown in FIG. 17), at least a portion of the signal line SL is covered by the buffer layer BUF, and at least a portion of an upper surface of the signal line SL is unexposed by the via v. For example, in the cross-section, a first portion of the signal line SL is covered by the buffer layer BUF, and a second portion of the signal line SL is not covered the buffer layer BUF. In the cross-section, an upper surface of the first portion of the signal line SL is unexposed by the via v, and an upper surface of the second portion of the signal line SL is exposed by the via v. The first portion is on a side of the second portion away from the channel region CR.

In the cross-section, an upper surface of the signal line SL is partially covered by the second electrode part E1-2, and partially covered by the buffer layer BUF. In one example, in the cross-section, an upper surface of the first portion of the signal line SL is covered by the buffer layer BUF, and an upper surface of the second portion of the signal line SL is covered by the second electrode part E1-2. The first portion is on a side of the second portion away from the channel region CR.

In one example, in the cross-section, a first lateral surface of the signal line SL is covered by the buffer layer BUF, and a second lateral surface of the signal line SL is covered by the second electrode part E1-2. The first lateral surface is on a side of the second lateral surface away from the channel region CR.

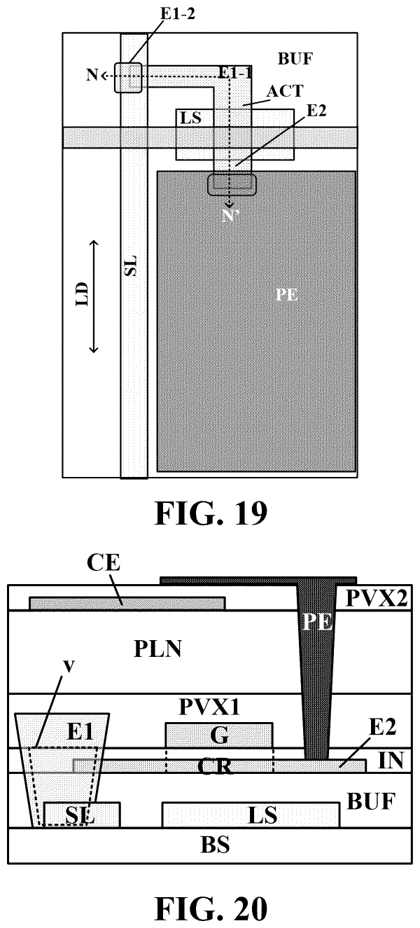

FIG. 19 is a plan view of an array substrate in some embodiments according to the present disclosure. FIG. 20 is a cross-sectional view of an array substrate in some embodiments according to the present disclosure. FIG. 21 is a schematic diagram illustrating the structure of a first electrode of the array substrate depicted in FIG. 20. Referring to FIG. 19 to FIG. 21, in some embodiments, in a cross-section along a plane perpendicular to the base substrate BS and perpendicular to a length direction LD along which the signal line SL extends, and intersecting the signal line SL, and the via v (e.g., the cross-section as shown in FIG. 20), at least a portion of the signal line SL is covered by the buffer layer BUF, and at least a portion of an upper surface of the signal line SL is unexposed by the via v. For example, in the cross-section, a first portion of the signal line SL is not covered the buffer layer BUF, and a second portion of the signal line SL is covered by the buffer layer BUF. In the cross-section, an upper surface of the first portion of the signal line SL is exposed by the via v, and an upper surface of the second portion of the signal line SL is unexposed by the via v. The first portion is on a side of the second portion away from the channel region CR.

In the cross-section, an upper surface of the signal line SL is partially covered by the second electrode part E1-2, and partially covered by the buffer layer BUF. In one example, in the cross-section, an upper surface of the first portion of the signal line SL is covered by the second electrode part E1-2, and an upper surface of the second portion of the signal line SL is covered by the buffer layer BUF. The first portion is on a side of the second portion away from the channel region CR.

In one example, in the cross-section, a first lateral surface of the signal line SL is covered by the second electrode part E1-2, and a second lateral surface of the signal line SL is covered by the buffer layer BUF. The first lateral surface is on a side of the second lateral surface away from the channel region CR.

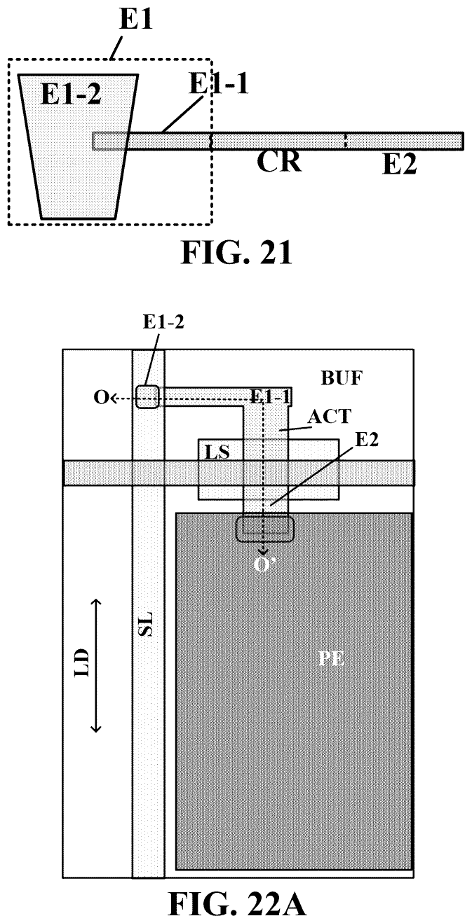

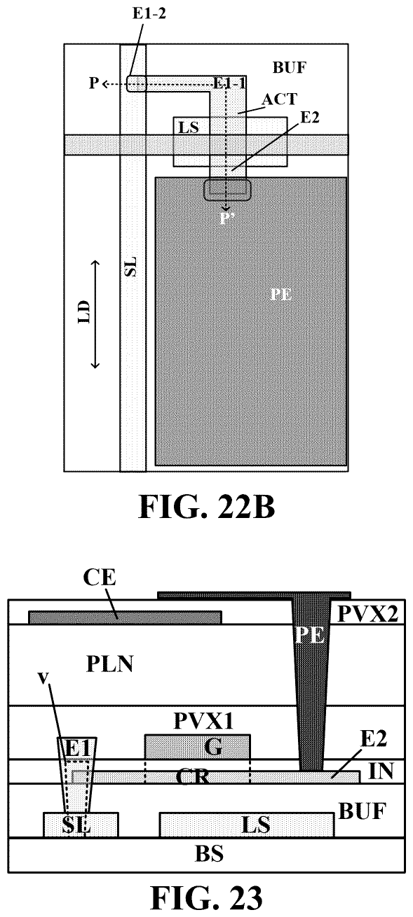

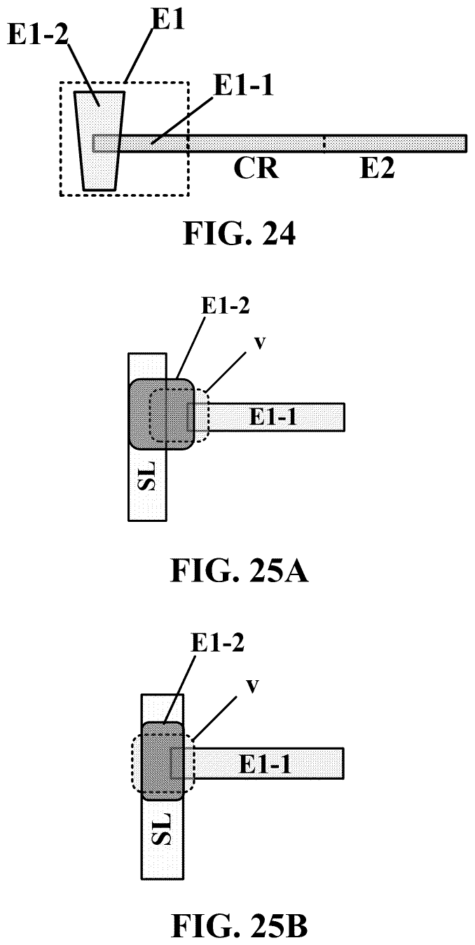

FIG. 22A is a plan view of an array substrate in some embodiments according to the present disclosure. FIG. 22B is a plan view of an array substrate in some embodiments according to the present disclosure. FIG. 23 is a cross-sectional view of an array substrate in some embodiments according to the present disclosure. FIG. 24 is a schematic diagram illustrating the structure of a first electrode of the array substrate depicted in FIG. 23. Referring to FIG. 22A, FIG. 22B, FIG. 23, and FIG. 24, in some embodiments, in a cross-section along a plane perpendicular to the base substrate BS and perpendicular to a length direction LD along which the signal line SL extends, and intersecting the signal line SL and the via v (e.g., the cross-section as shown in FIG. 23), at least a portion of the signal line SL is covered by the buffer layer BUF, and at least a portion of an upper surface of the signal line SL is unexposed by the via. For example, in the cross-section, a central portion of the signal line SL is not covered the buffer layer BUF, and two side portions of the signal line SL are covered by the buffer layer BUF. In the cross-section, an upper surface of the central portion of the signal line SL is exposed by the via v, and upper surfaces of the two side portions of the signal line SL are unexposed by the via v.

In the cross-section, an upper surface of the signal line SL is partially covered by the second electrode part E1-2, and partially covered by the buffer layer BUF. In one example, in the cross-section, an upper surface of the central portion of the signal line SL is covered by the second electrode part E1-2, and upper surfaces of the two side portions of the signal line SL are covered by the buffer layer BUF.

In one example, in the cross-section, two lateral surfaces of the signal line SL is covered by the buffer layer BUF.

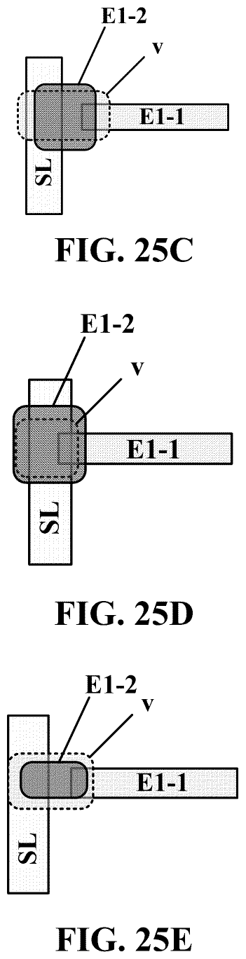

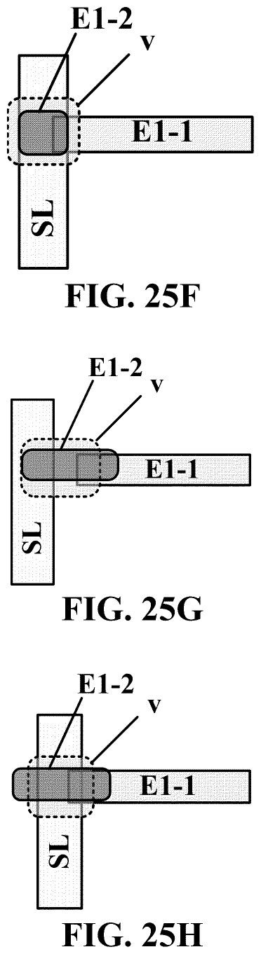

The second electrode part may be arranged in various positions with respect to the first electrode part, the signal line, and the via. FIG. 25A to FIG. 25H illustrate various arrangements of a second electrode part with respect to adjacent components in an array substrate in some embodiments according to the present disclosure. Referring to FIG. 25A to FIG. 25H, an orthographic projection of the second electrode part E1-2 on the base substrate partially overlaps with an orthographic projection of the first electrode part E1-1 on the base substrate, and partially overlaps with an orthographic projection of the signal line SL on the base substrate. In some embodiments, referring to FIG. 25B, FIG. 25D, FIG. 25F, and FIG. 25H, an orthographic projection of the first electrode part E1-1 on a base substrate partially overlaps with an orthographic projection of the signal line SL on the base substrate. In some embodiments, referring to FIG, 25A, FIG. 25C, FIG. 25E, and FIG. 25G, an orthographic projection of the first electrode part E1-1 on a base substrate partially is non-overlapping with an orthographic projection of the signal line SL on the base substrate.

Referring to FIG. 25A to FIG. 25H, an orthographic projection of the via v on the base substrate partially overlaps with an orthographic projection of the first electrode part E1-1 on the base substrate, and partially overlaps with an orthographic projection of the signal line SL on the base substrate. In some embodiments, referring to FIG. 25D, an orthographic projection of the second electrode part E1-2 on a base substrate fully covers an orthographic projection of the via v on the base substrate. In some embodiments, referring to FIG. 25E and FIG. 25F, an orthographic projection of the via v on a base substrate fully covers an orthographic projection of the second electrode part E1-2 on the base substrate. In some embodiments, referring to FIG. 25A, FIG. 25B, FIG. 25C, FIG. 25G, and FIG. 25H, an orthographic projection of the second electrode part E1-2 on a base substrate partially overlaps with an orthographic projection of the via v on the base substrate.

In related array substrates, parasitic capacitance along the data line significantly limits the pixel-per-inch resolution and the refresh rate of the array substrate. The present disclosure provides an array substrate that obviates the limitations in the related array substrates. Moreover, the present array substrate significantly decreases the resistance between the source electrode and the data line, thereby improving Ion parameter of the thin film transistor.

In another aspect, the present invention provides a display apparatus, including the array substrate described herein or fabricated by a method described herein, and one or more integrated circuits connected to the array substrate. Examples of appropriate display apparatuses include, but are not limited to, an electronic paper, a mobile phone, a tablet computer, a television, a monitor, a notebook computer, a digital album, a GPS, etc. Optionally, the display apparatus is a liquid crystal display apparatus. Optionally, the display apparatus is an organic light emitting diode display apparatus. Optionally, the display apparatus is a micro light emitting diode display apparatus. Optionally, the display apparatus is a mini light emitting diode display apparatus.

In another aspect, the present disclosure provides a method of fabricating an array substrate. In some embodiments, the method includes forming a signal line on a base substrate; forming a buffer layer on a side of the signal line away from the base substrate; and forming a first electrode, and forming an active layer on a side of the buffer layer away from the base substrate; the active layer comprises a first electrode region, a second electrode region and a channel region between the first electrode region and the second electrode region; the first electrode region comprising a first electrode, and the second electrode region comprising a second electrode. Optionally, the method further comprises forming a via extending at least through the buffer layer, and the first electrode is formed to extend through the via to connect to the signal line. Optionally, the second electrode and at least a portion of the first electrode comprise a same material as the channel region, and are subject to a process that make them conductive, The channel region has a conductivity different from a conductivity of the first electrode and different from a conductivity of the second electrode.

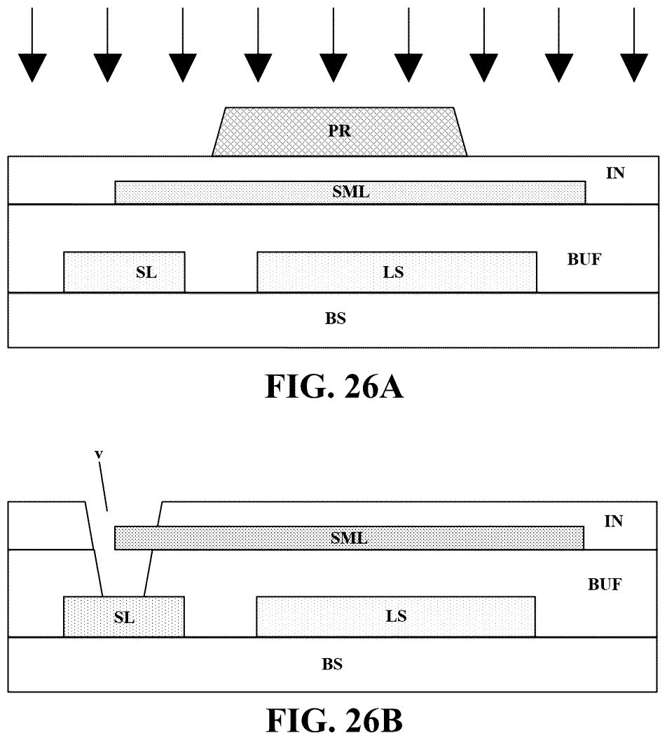

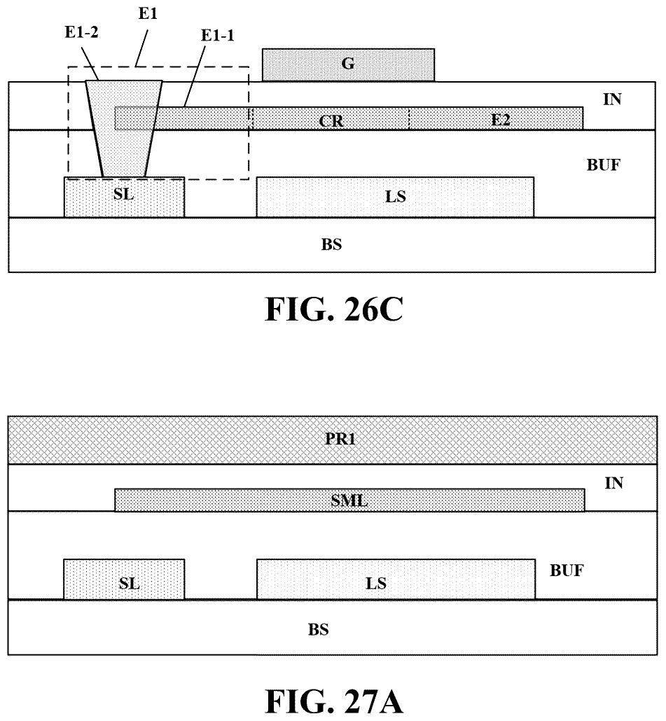

FIG. 26A to FIG. 26C illustrate a process of fabricating an array substrate in some embodiments according to the present disclosure. Referring to FIG. 26A, a signal line SL and a light shield LS are formed on a base substrate BS; a buffer layer BUF is formed on a side of the signal line SL and the light shield LS away from the base substrate BS; a semiconductor material layer SML is formed on a side of the buffer layer BUF away from the base substrate BS; an insulating layer IN is formed on a side of the semiconductor material layer SML away from the base substrate BS; a photoresist layer PR is formed on a side of the insulating layer IN away from the base substrate BS; and a lightly doped drain process is performed to make portions of the semiconductor material layer SML corresponding to the first electrode and the second electrode more conductive. An orthographic projection of the photoresist layer PR on the base substrate BS overlaps with an orthographic projection of a portion of the semiconductor material layer SML corresponding to the channel region CR on the base substrate BS. Subsequent to the lightly doped drain process, the portions of the semiconductor material layer SML corresponding to the first electrode and the second electrode become more conductive.

Referring to FIG. 26B, a via v is formed to extend through the insulating layer IN and the buffer layer BUF, exposing an upper surface of at least a portion (e.g., a central portion as depicted in FIG. 26B) of the signal line SL. A portion of the semiconductor material layer SML corresponding to the first electrode extends partially into the via v.

Referring to FIG. 26C, an electrode material is deposited and patterned to form a gate electrode G and a second electrode part E1-2. The second electrode part E1-2 and a first electrode part E1-1 (a portion of the semiconductor material layer SML subject to the lightly doped drain process) constitute the first electrode E1.

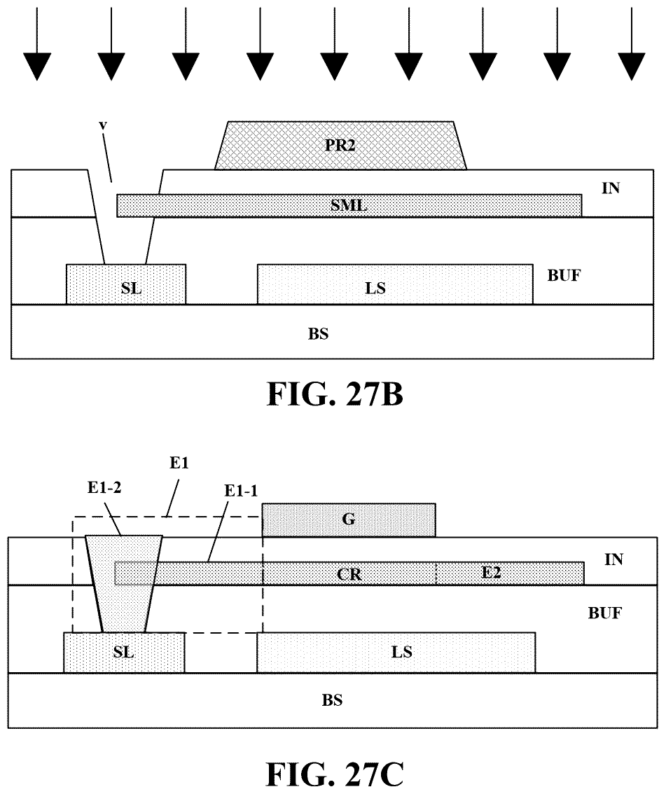

FIG. 27A to FIG. 27C illustrate a process of fabricating an array substrate in some embodiments according to the present disclosure. FIG. 27A to FIG. 27C shows a process in which a half-tone mask is used for fabrication the array substrate. Referring to FIG. 27A, a signal line SL and a light shield LS are formed on a base substrate BS; a buffer layer BUF is formed on a side of the signal line SL and the light shield LS away from the base substrate BS; a semiconductor material layer SML is formed on a side of the buffer layer BUF away from the base substrate BS; an insulating layer IN is formed on a side of the semiconductor material layer SML away from the base substrate BS; a first photoresist layer PR1 is formed on a side of the insulating layer IN away from the base substrate BS. The first photoresist layer PR1 is exposed using a half-tone mask plate, the exposed photoresist layer is developed to obtain a photoresist pattern, the photoresist pattern including a first section corresponding to the via; and a second section outside the first section. The first section includes a first zone corresponding to the channel region; and a second zone corresponding to remaining parts of the first section; wherein, the depth of the first zone is larger than that of the second zone. The photoresist material is removed in the second section. The process further includes etching the insulating layer IN and the buffer layer BUF in the second section, exposing an upper surface of at least a portion of the signal line SL in the second section, thereby forming the via v. The process further includes ashing the developed photoresist layer, thereby removing the photoresist material in the second zone while maintaining the photoresist material in the first zone; thereby forming a second photoresist layer PR2 in a region corresponding to the channel region.

Referring to FIG. 27B, a lightly doped drain process is performed to make portions of the semiconductor material layer SML corresponding to the first electrode and the second electrode more conductive. An orthographic projection of the second photoresist layer PR2 on the base substrate BS overlaps with an orthographic projection of a portion of the semiconductor material layer SML corresponding to the channel region on the base substrate BS. Subsequent to the lightly doped drain process, the portions of the semiconductor material layer SML corresponding to the first electrode and the second electrode become more conductive.

Referring to FIG. 27C, an electrode material is deposited and patterned to form a gate electrode G and a second electrode part E1-2. The second electrode part E1-2 and a first electrode part E1-1 (a portion of the semiconductor material layer SML subject to the lightly doped drain process) constitute the first electrode E1.

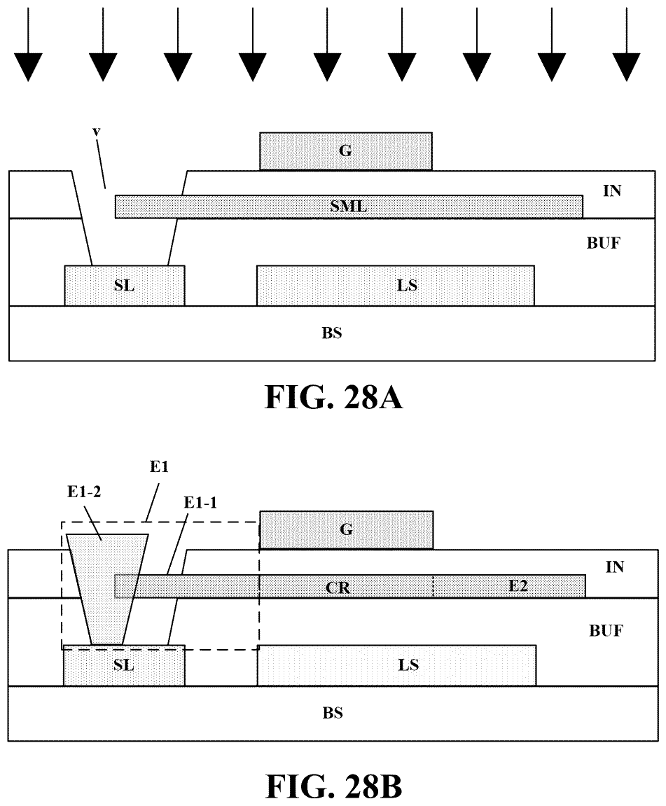

FIG. 28A to FIG. 28B illustrate a process of fabricating an array substrate in some embodiments according to the present disclosure. Referring to FIG. 28A, a signal line SL and a light shield LS are formed on a base substrate BS; a buffer layer BUF is formed on a side of the signal line SL and the light shield LS away from the base substrate BS; a semiconductor material layer SML is formed on a side of the buffer layer BUF away from the base substrate BS; an insulating layer IN is formed on a side of the semiconductor material layer SML away from the base substrate BS; a via v is formed to extend through the insulating layer IN and the buffer layer BUF, exposing an upper surface of at least a portion (e.g., a central portion as depicted in FIG. 28A) of the signal line SL. A portion of the semiconductor material layer SML corresponding to the first electrode extends partially into the via v. A gate electrode G is formed on a side of the insulating layer IN away from the base substrate BS.

Referring to FIG. 28A, using the gate electrode G as a mask plate, a lightly doped drain process is then performed to make portions of the semiconductor material layer SML corresponding to the first electrode and the second electrode more conductive. An orthographic projection of the gate electrode G on the base substrate BS overlaps with an orthographic projection of a portion of the semiconductor material layer SML corresponding to the channel region on the base substrate BS. Subsequent to the lightly doped drain process, the portions of the semiconductor material layer SML corresponding to the first electrode and the second electrode become more conductive.

Referring to FIG. 28B, an electrode material is deposited and patterned to form a second electrode part E1-2. The second electrode part E1-2 and a first electrode part E1-1 (a portion of the semiconductor material layer SML subject to the lightly doped drain process) constitute the first electrode E1.

In some embodiments, the insulating layer IN is formed to extend substantially throughout the array substrate, as shown in FIG. 26A to FIG. 26C, FIG. 27A to FIG. 27C, and FIG. 28A to FIG. 28B.

In some embodiments, the insulating layer is not formed to extend substantially throughout the array substrate. For example, an orthographic projection of the insulating layer on the base substrate is at least partially non-overlapping with an orthographic projection of the signal line on the base substrate, and is at least partially non-overlapping with an orthographic projection of the first electrode or the second electrode on the base substrate.

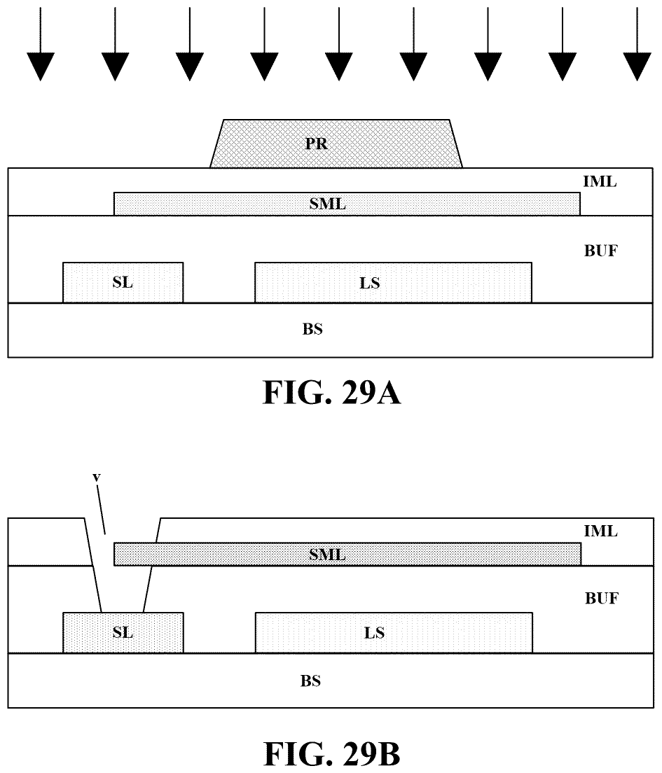

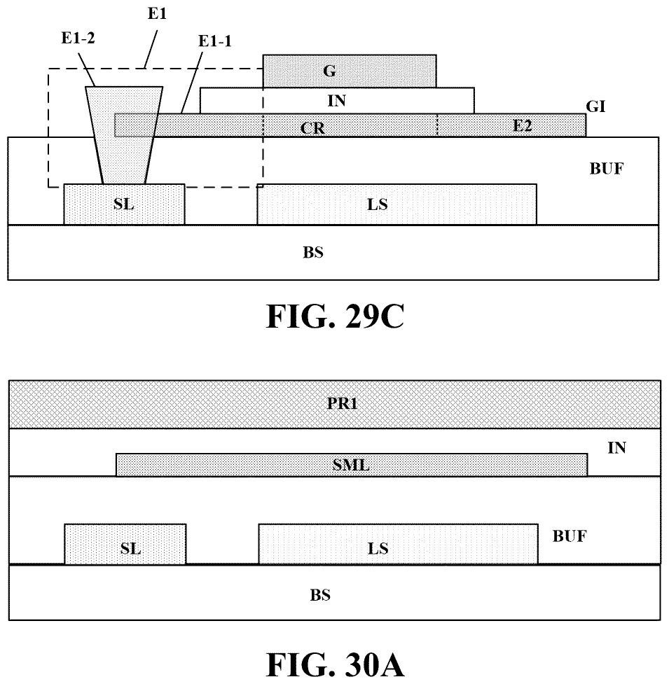

FIG. 29A to FIG. 29C illustrate a process of fabricating an array substrate in some embodiments according to the present disclosure. The process shown in FIG. 29A to FIG. 29C is similar to the process shown in FIG. 26A to FIG. 26C, but differs from the process shown in FIG. 26A to FIG. 26C at least in that the insulating layer IN is not formed to extend substantially throughout the array substrate.

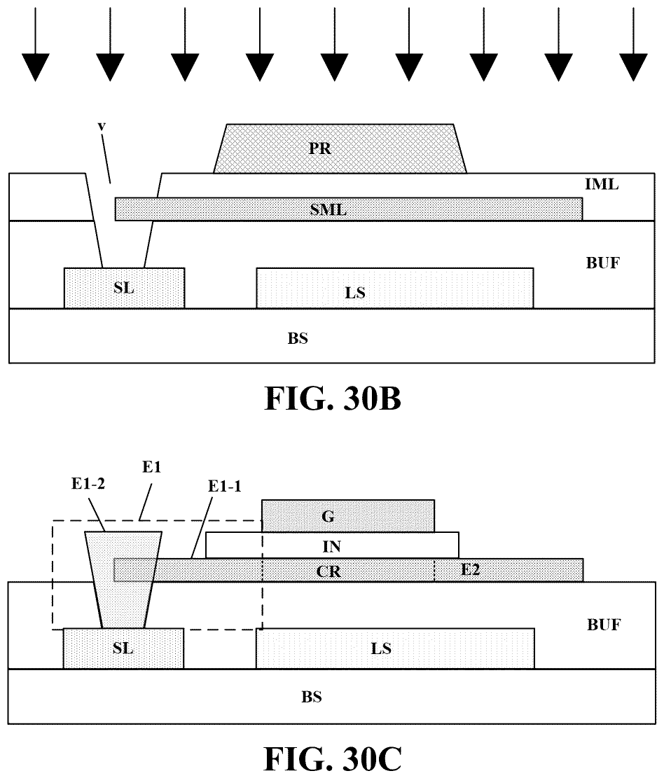

FIG. 30A to FIG. 30C illustrate a process of fabricating an array substrate in some embodiments according to the present disclosure. The process shown in FIG. 30A to FIG. 30C is similar to the process shown in FIG. 27A to FIG. 27C, but differs from the process shown in FIG. 27A to FIG. 27C at least in that the insulating layer IN is not formed to extend substantially throughout the array substrate.

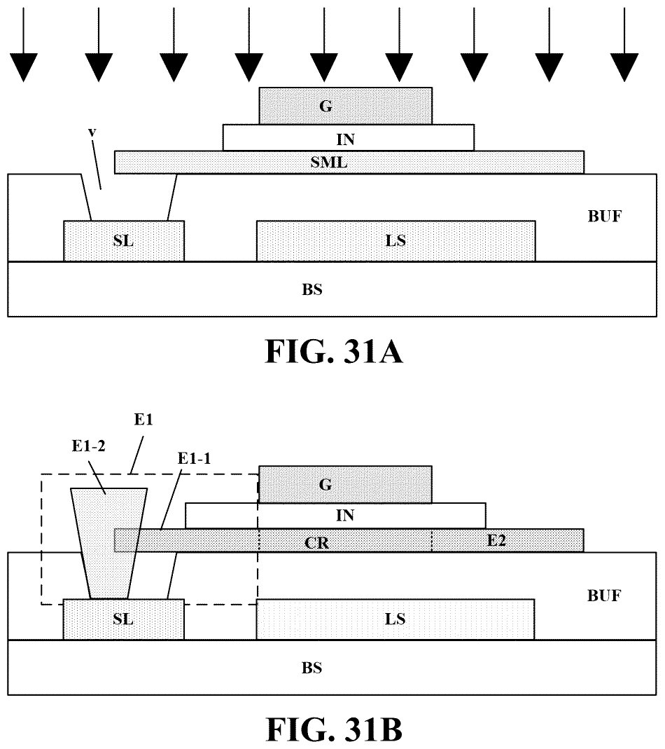

FIG. 31A to FIG. 31B illustrate a process of fabricating an array substrate in some embodiments according to the present disclosure. The process shown in FIG. 31A to FIG. 31B is similar to the process shown in FIG. 28A to FIG. 28B, but differs from the process shown in FIG. 28A to FIG. 28B at least in that the insulating layer IN is not formed to extend substantially throughout the array substrate.

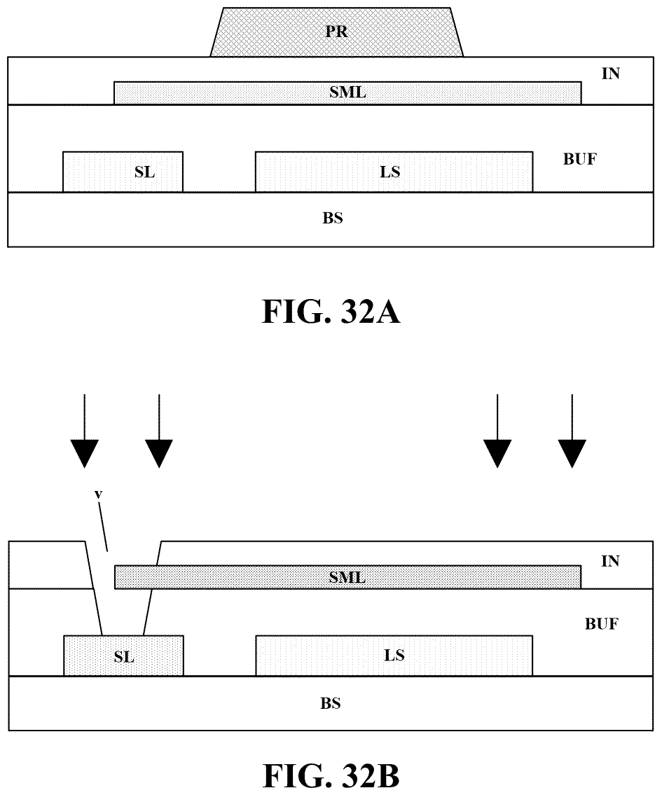

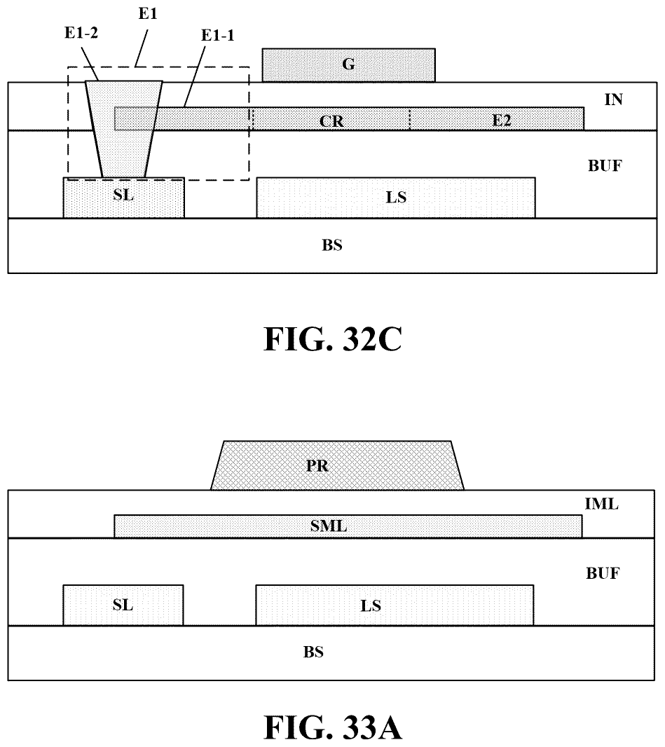

FIG. 32A to FIG. 32C illustrate a process of fabricating an array substrate in some embodiments according to the present disclosure. The process shown in FIG. 32A to FIG. 32C is similar to the process shown in FIG. 26A to FIG. 26C, but differs from the process shown in FIG. 26A to FIG. 26C at least in that the lightly doped drain process is performed using a mask plate. In one example, the lightly doped drain process is performed only on a portion of the semiconductor material layer SML extending into the via y and on a portion of the semiconductor material layer SML corresponding to the second electrode E2.

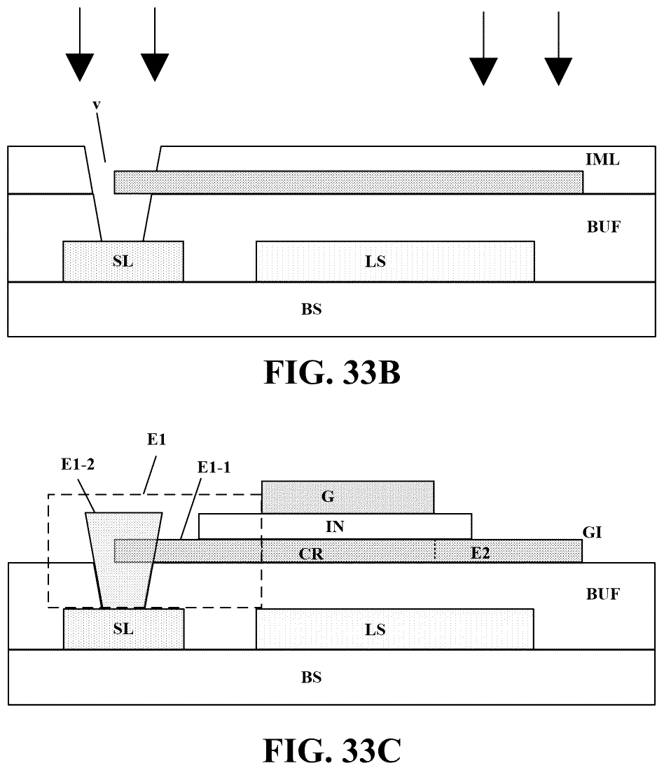

FIG. 33A to FIG. 33C illustrate a process of fabricating an array substrate in some embodiments according to the present disclosure. The process shown in FIG. 33A to FIG. 33B is similar to the process shown in FIG. 32A to FIG. 32C, but differs from the process shown in FIG. 32A to FIG. 32C at least in that the insulating layer IN is not formed to extend substantially throughout the array substrate.

Example 1: In one example, a method of fabricating an array substrate includes cleaning a base substrate; depositing an electrode material layer having a thickness between 100 nm and 1000 nm on the base substrate, the electrode material including a molybdenum-aluminum-aluminum laminated structure, a molybdenum-neodymium-copper laminated structure, a MTD-copper laminated structure, or a MTD-copper-MTD laminated structure; patterning the electrode material layer to formed a light shield LS and a signal line SL on the base substrate BS; depositing (e.g., by a chemical vapor deposition process) an insulating material (silicon oxide, or silicon nitride/silicon oxide) on the base substrate to form a buffer layer having a thickness between 100 nm to 700 nm; sputtering indium gallium zinc oxide on the base substrate to a thickness between 10 nm to 80 nm; patterning the indium gallium zinc oxide material to form a semiconductor material layer; forming an insulating layer on a side of the semiconductor material layer away from the base substrate using a chemical vapor deposition process or an atomic layer deposition process and using silicon oxide as the insulating material; performing a lightly doped drain process on the semiconductor material layer; etching the insulating layer and the buffer layer to form a via extending through the insulating layer and the buffer layer and exposing an upper surface of at least a portion of the signal line SL; sputtering an electrode material layer on a side of the insulating layer and the buffer layer away from the base substrate having a thickness between 200 nm and 1200 nm, the electrode material including a molybdenum-neodymium-copper laminated structure, a MTD-copper laminated structure, or a MTD-copper-MTD laminated structure; patterning the electrode material layer to form the second electrode part and the gate electrode; depositing (e.g., by a plasma-enhanced chemical vapor deposition process) an insulating material (silicon oxide, or silicon nitride/silicon oxide) on the base substrate to form a first passivation layer having a thickness between 200 nm to 400 nm; coating a resin layer having a thickness between 2 μm to 3 μm on the first passivation layer, depositing a conductive material layer having a thickness between 40 nm to 100 nm using indium gallium zinc oxide or indium zinc oxide on the resin layer, and patterning the conductive material layer to form a common electrode; depositing (e.g., by a chemical vapor deposition process) an insulating material (silicon oxide, or silicon nitride/silicon oxide) on the base substrate to form a second passivation layer having a thickness between 100 nm to 300 nm; depositing a conductive material layer having a thickness between 40 nm to 135 nm using indium zinc oxide on the second passivation layer, and patterning the conductive material layer to form a pixel electrode. The process described in Example 1 corresponds to the process depicted in FIG. 26A to FIG. 26C.

Example 2: In one example, a method of fabricating an array substrate includes cleaning a base substrate; depositing an electrode material layer having a thickness between 100 nm and 1000 nm on the base substrate, the electrode material including a molybdenum-aluminum-aluminum laminated structure, a molybdenum-neodymium-copper laminated structure, a MTD-copper laminated structure, or a MTD-copper-MTD laminated structure; patterning the electrode material layer to formed a light shield LS and a signal line SL on the base substrate BS; depositing (e.g., by a chemical vapor deposition process) an insulating material (silicon oxide, or silicon nitride/silicon oxide) on the base substrate to form a buffer layer having a thickness between 100 nm to 700 nm; sputtering indium gallium zinc oxide on the base substrate to a thickness between 10 nm to 80 nm; patterning the indium gallium zinc oxide material to form a semiconductor material layer; forming an insulating material layer on a side of the semiconductor material layer away from the base substrate using a chemical vapor deposition process or an atomic layer deposition process and using silicon oxide as the insulating material; performing a lightly doped drain process on the semiconductor material layer; etching the insulating layer and the buffer layer to form a via extending through the insulating layer and the buffer layer and exposing an upper surface of at least a portion of the signal line SL; sputtering an electrode material layer on a side of the insulating layer and the buffer layer away from the base substrate having a thickness between 200 nm and 1200 nm, the electrode material including a molybdenum-neodymium-copper laminated structure, a MTD-copper laminated structure, or a MTD-copper-MTD laminated structure; patterning the electrode material layer to form the second electrode part and the gate electrode; patterning the insulating material layer to form an insulating layer, the insulating layer does not extend substantially throughout the array substrate, an orthographic projection of the insulating layer on the base substrate is at least partially non-overlapping with an orthographic projection of the signal line on the base substrate, and is at least partially non-overlapping with an orthographic projection of the first electrode or the second electrode on the base substrate; depositing (e.g., by a plasma-enhanced chemical vapor deposition process) an insulating material (silicon oxide, or silicon nitride/silicon oxide) on the base substrate to form a first passivation layer having a thickness between 200 nm to 400 nm; coating a resin layer having a thickness between 2 μm to 3 μm on the first passivation layer; depositing a conductive material layer having a thickness between 40 nm to 100 nm using indium gallium zinc oxide or indium zinc oxide on the resin layer, and patterning the conductive material layer to form a common electrode; depositing (e.g., by a chemical vapor deposition process) an insulating material (silicon oxide, or silicon nitride/silicon oxide) on the base substrate to form a second passivation layer having a thickness between 100 nm to 300 nm; depositing a conductive material layer having a thickness between 40 nm to 135 nm using indium zinc oxide on the second passivation layer, and patterning the conductive material layer to form a pixel electrode. The process described in Example 2 corresponds to the process depicted in FIG. 29A to FIG. 29C.

Example 3: In one example, a method of fabricating an array substrate includes cleaning a base substrate; depositing an electrode material layer having a thickness between 100 nm and 1000 nm on the base substrate, the electrode material including a molybdenum-aluminum-aluminum laminated structure, a molybdenum-neodymium-copper laminated structure, a MTD-copper laminated structure, or a MTD-copper-MTD laminated structure; patterning the electrode material layer to formed a light shield LS and a signal line SL on the base substrate BS; depositing (e.g., by a chemical vapor deposition process) an insulating material (silicon oxide, or silicon nitride/silicon oxide) on the base substrate to form a buffer layer having a thickness between 100 nm to 700 nm; sputtering indium gallium zinc oxide on the base substrate to a thickness between 10 nm to 80 nm; patterning the indium gallium zinc oxide material to form a semiconductor material layer; forming an insulating layer on a side of the semiconductor material layer away from the base substrate using a chemical vapor deposition process or an atomic layer deposition process and using silicon oxide as the insulating material; forming a first photoresist layer on a side of the insulating layer away from the base substrate; exposing and developing the first photoresist layer using a half-tone mask plate; etching the insulating layer and the buffer layer, thereby forming a via extending through the insulating layer and the buffer layer to expose an upper surface of at least a portion of the signal line; forming a second photoresist layer in a region corresponding to the channel region; performing a lightly doped drain process on the semiconductor material layer using the second photoresist layer as a mask plate; sputtering an electrode material layer on a side of the insulating layer and the buffer layer away from the base substrate having a thickness between 200 nm and 1200 nm, the electrode material including a molybdenum-neodymium-copper laminated structure, a MTD-copper laminated structure, or a MTD-copper-MTD laminated structure; patterning the electrode material layer to form the second electrode part and the gate electrode; depositing (e.g., by a plasma-enhanced chemical vapor deposition process) an insulating material (silicon oxide, or silicon nitride/silicon oxide) on the base substrate to form a first passivation layer having a thickness between 200 nm to 400 nm; coating a resin layer having a thickness between 2 μm to 3 μm on the first passivation layer; depositing a conductive material layer having a thickness between 40 nm to 100 nm using indium gallium zinc oxide or indium zinc oxide on the resin layer, and patterning the conductive material layer to form a common electrode; depositing (e.g., by a chemical vapor deposition process) an insulating material (silicon oxide, or silicon nitride/silicon oxide) on the base substrate to form a second passivation layer having a thickness between 100 nm to 300 nm; depositing a conductive material layer having a thickness between 40 nm to 135 nm using indium zinc oxide on the second passivation layer, and patterning the conductive material layer to form a pixel electrode. The process described in Example 3 corresponds to the process depicted in FIG. 27A to FIG. 27C.

Example 4: In one example, a method of fabricating an array substrate includes cleaning a base substrate; depositing an electrode material layer having a thickness between 100 nm and 1000 nm on the base substrate, the electrode material including a molybdenum-aluminum-aluminum laminated structure, a molybdenum-neodymium-copper laminated structure, a MTD-copper laminated structure, or a MTD-copper-MTD laminated structure; patterning the electrode material layer to formed a light shield LS and a signal line SL on the base substrate BS; depositing (e.g., by a chemical vapor deposition process) an insulating material (silicon oxide, or silicon nitride/silicon oxide) on the base substrate to form a buffer layer having a thickness between 100 nm to 700 nm; sputtering indium gallium zinc oxide on the base substrate to a thickness between 10 nm to 80 nm; patterning the indium gallium zinc oxide material to form a semiconductor material layer; forming an insulating material layer on a side of the semiconductor material layer away from the base substrate using a chemical vapor deposition process or an atomic layer deposition process and using silicon oxide as the insulating material; forming a first photoresist layer on a side of the insulating material layer away from the base substrate; exposing and developing the first photoresist layer using a half-tone mask plate; etching the insulating material layer and the buffer layer, thereby forming a via extending through the insulating material layer and the buffer layer to expose an upper surface of at least a portion of the signal line: forming a second photoresist layer in a region corresponding to the channel region; performing a lightly doped drain process on the semiconductor material layer using the second photoresist layer as a mask plate; sputtering an electrode material layer on a side of the insulating material layer and the buffer layer away from the base substrate having a thickness between 200 nm and 1200 nm, the electrode material including a molybdenum-neodymium-copper laminated structure, a MTD-copper laminated structure, or a MTD-copper-MTD laminated structure; patterning the electrode material layer to form the second electrode part and the gate electrode; patterning the insulating material layer to form an insulating layer, the insulating layer does not extend substantially throughout the array substrate, an orthographic projection of the insulating layer on the base substrate is at least partially non-overlapping with an orthographic projection of the signal line on the base substrate, and is at least partially non-overlapping with an orthographic projection of the first electrode or the second electrode on the base substrate; depositing (e.g., by a plasma-enhanced chemical vapor deposition process) an insulating material (silicon oxide, or silicon nitride/silicon oxide) on the base substrate to form a first passivation layer having a thickness between 200 nm to 400 nm; coating a resin layer having a thickness between 2 μm to 3 μm on the first passivation layer, depositing a conductive material layer having a thickness between 40 nm to 100 nm using indium gallium zinc oxide or indium zinc oxide on the resin layer, and patterning the conductive material layer to form a common electrode; depositing (e.g., by a chemical vapor deposition process) an insulating material (silicon oxide, or silicon nitride/silicon oxide) on the base substrate to form a second passivation layer having a thickness between 100 nm to 300 nm; depositing a conductive material layer having a thickness between 40 nm to 135 nm using indium zinc oxide on the second passivation layer, and patterning the conductive material layer to form a pixel electrode. The process described in Example 4 corresponds to the process depicted in FIG. 30A to FIG. 30C.

Example 5: In one example, a method of fabricating an array substrate includes cleaning a base substrate; depositing an electrode material layer having a thickness between 100 nm and 1000 nm on the base substrate, the electrode material including a molybdenum-aluminum-aluminum laminated structure, a molybdenum-neodymium-copper laminated structure, a MTD-copper laminated structure, or a MTD-copper-MTD laminated structure; patterning the electrode material layer to formed a light shield LS and a signal line SL on the base substrate BS; depositing (e.g., by a chemical vapor deposition process) an insulating material (silicon oxide, or silicon nitride/silicon oxide) on the base substrate to form a buffer layer having a thickness between 100 nm to 700 nm; sputtering indium gallium zinc oxide on the base substrate to a thickness between 10 nm to 80 nm; patterning the indium gallium zinc oxide material to form a semiconductor material layer; forming an insulating layer on a side of the semiconductor material layer away from the base substrate using a chemical vapor deposition process or an atomic layer deposition process and using silicon oxide as the insulating material; etching the insulating layer and the buffer layer using a mask plate to form a via extending through the insulating layer and the buffer layer and exposing an upper surface of at least a portion of the signal line SL; performing a lightly doped drain process, using the same mask plate for forming the via v, on a portion of the semiconductor material layer extending into the via v; sputtering an electrode material layer on a side of the insulating layer and the buffer layer away from the base substrate having a thickness between 200 nm and 1200 nm, the electrode material including a molybdenum-neodymium-copper laminated structure, a MTD-copper laminated structure, or a MTD-copper-MTD laminated structure; patterning the electrode material layer to form the second electrode part and the gate electrode; depositing (e.g., by a plasma-enhanced chemical vapor deposition process) an insulating material (silicon oxide, or silicon nitride/silicon oxide) on the base substrate to form a first passivation layer having a thickness between 200 nm to 400 nm; coating a resin layer having a thickness between 2 μm to 3 μm on the first passivation layer; depositing a conductive material layer having a thickness between 40 nm to 100 nm using indium gallium zinc oxide or indium zinc oxide on the resin layer, and patterning the conductive material layer to form a common electrode; depositing (e.g., by a chemical vapor deposition process) an insulating material (silicon oxide, or silicon nitride/silicon oxide) on the base substrate to form a second passivation layer having a thickness between 100 nm to 300 nm; depositing a conductive material layer having a thickness between 40 nm to 135 am using indium zinc oxide on the second passivation layer, and patterning the conductive material layer to form a pixel electrode. The process described in Example 5 corresponds to the process depicted in FIG. 32A to FIG. 32C.

Example 6: In one example, a method of fabricating an array substrate includes cleaning a base substrate; depositing an electrode material layer having a thickness between 100 nm and 1000 nm on the base substrate, the electrode material including a molybdenum-aluminum-aluminum laminated structure, a molybdenum-neodymium-copper laminated structure, a MTD-copper laminated structure, or a MTD-copper-MTD laminated structure; patterning the electrode material layer to formed a light shield LS and a signal line SL on the base substrate BS; depositing (e.g., by a chemical vapor deposition process) an insulating material (silicon oxide, or silicon nitride/silicon oxide) on the base substrate to form a buffer layer having a thickness between 100 nm to 700 nm; sputtering indium gallium zinc oxide on the base substrate to a thickness between 10 nm to 80 nm; patterning the indium gallium zinc oxide material to form a semiconductor material layer; forming an insulating layer on a side of the semiconductor material layer away from the base substrate using a chemical vapor deposition process or an atomic layer deposition process and using silicon oxide as the insulating material; etching the insulating layer and the buffer layer using a mask plate to form a via extending through the insulating layer and the buffer layer and exposing an upper surface of at least a portion of the signal line SL; performing a lightly doped drain process, using the same mask plate for forming the via v, on a portion of the semiconductor material layer extending into the via v; sputtering an electrode material layer on a side of the insulating layer and the buffer layer away from the base substrate having a thickness between 200 nm and 1200 nm, the electrode material including a molybdenum-neodymium-copper laminated structure, a MTD-copper laminated structure, or a MTD-copper-MTD laminated structure; patterning the electrode material layer to form the second electrode part and the gate electrode; patterning the insulating material layer to form an insulating layer, the insulating layer does not extend substantially throughout the array substrate, an orthographic projection of the insulating layer on the base substrate is at least partially non-overlapping with an orthographic projection of the signal line on the base substrate, and is at least partially non-overlapping with an orthographic projection of the first electrode or the second electrode on the base substrate; depositing (e.g., by a plasma-enhanced chemical vapor deposition process) an insulating material (silicon oxide, or silicon nitride/silicon oxide) on the base substrate to form a first passivation layer having a thickness between 200 nm to 400 nm; coating a resin layer having a thickness between 2 μm to 3 μm on the first passivation layer; depositing a conductive material layer having a thickness between 40 nm to 100 nm using indium gallium zinc oxide or indium zinc oxide on the resin layer, and patterning the conductive material layer to form a common electrode; depositing (e.g., by a chemical vapor deposition process) an insulating material (silicon oxide, or silicon nitride/silicon oxide) on the base substrate to form a second passivation layer having a thickness between 100 nm to 300 nm; depositing a conductive material layer having a thickness between 40 nm to 135 nm using indium zinc oxide on the second passivation layer, and patterning the conductive material layer to form a pixel electrode. The process described in Example 6 corresponds to the process depicted in FIG. 33A to FIG. 33C.

Example 7: In one example, a method of fabricating an array substrate includes cleaning a base substrate; depositing an electrode material layer having a thickness between 100 nm and 1000 nm on the base substrate, the electrode material including a molybdenum-aluminum-aluminum laminated structure, a molybdenum-neodymium-copper laminated structure, a MTD-copper laminated structure, or a MTD-copper-MTD laminated structure; patterning the electrode material layer to formed a light shield LS and a signal line SL on the base substrate BS; depositing (e.g., by a chemical vapor deposition process) an insulating material (silicon oxide, or silicon nitride/silicon oxide) on the base substrate to form a buffer layer having a thickness between 100 nm to 700 nm; sputtering indium gallium zinc oxide on the base substrate to a thickness between 10 nm to 80 nm; patterning the indium gallium zinc oxide material to form a semiconductor material layer; forming an insulating layer on a side of the semiconductor material layer away from the base substrate using a chemical vapor deposition process or an atomic layer deposition process and using silicon oxide as the insulating material; etching the insulating layer and the buffer layer to form a via extending through the insulating layer and the buffer layer and exposing an upper surface of at least a portion of the signal line SL; sputtering an electrode material layer on a side of the insulating layer and the buffer layer away from the base substrate having a thickness between 200 nm and 1200 nm, the electrode material including a molybdenum-neodymium-copper laminated structure, a MTD-copper laminated structure, or a MTD-copper-MTD laminated structure; patterning the electrode material layer to form the gate electrode; performing a lightly doped drain process on the semiconductor material layer using the gate electrode as a mask plate; sputtering an electrode material layer having a thickness between 200 nm and 1200 nm, the electrode material including a molybdenum-neodymium-copper laminated structure, a MTD-copper laminated structure, or a MTD-copper-MTD laminated structure; patterning the electrode material layer to form the second electrode part at least partially in the via v; depositing (e.g., by a plasma-enhanced chemical vapor deposition process) an insulating material (silicon oxide, or silicon nitride/silicon oxide) on the base substrate to form a first passivation layer having a thickness between 200 nm to 400 nm; coating a resin layer having a thickness between 2 μm to 3 μm on the first passivation layer; depositing a conductive material layer having a thickness between 40 nm to 100 nm using indium gallium zinc oxide or indium zinc oxide on the resin layer, and patterning the conductive material layer to form a common electrode; depositing (e.g., by a chemical vapor deposition process) an insulating material (silicon oxide, or silicon nitride/silicon oxide) on the base substrate to form a second passivation layer having a thickness between 100 nm to 300 nm; depositing a conductive material layer having a thickness between 40 nm to 135 nm using indium zinc oxide on the second passivation layer, and patterning the conductive material layer to form a pixel electrode. The process described in Example 7 corresponds to the process depicted in FIG. 28A to FIG. 28B.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. An array substrate, comprising:
a base substrate;
a signal line on the base substrate;
a buffer layer on a side of the signal line away from the base substrate; and
an active layer on a side of the buffer layer away from the base substrate; the active layer comprises a first electrode region, a second electrode region, and a channel region between the first electrode region and the second electrode region; the first electrode region comprising a first electrode, and the second electrode region comprising a second electrode;
wherein the first electrode extends through a via extending at least through the buffer layer to connect to the signal line;
the second electrode and at least a portion of the first electrode comprise a same material as the channel region; and
the channel region has a conductivity different from a conductivity of the first electrode and different from a conductivity of the second electrode.

2. The array substrate of claim 1, wherein a material of the channel region, the second electrode, and at least a portion of the first electrode comprise M1OₐN_{b}, wherein M1 is a single metal or a combination of metals, a>0, and b≥0, O standing for oxygen element, N standing for nitrogen element.

3. The array substrate of claim 1, wherein the channel region, the second electrode, and at least a portion of the first electrode are parts of a unitary structure.

4. The array substrate of claim 3, wherein the channel region, the first electrode, and the second electrode are parts of a unitary structure, and comprise M1OₐN_{b}, wherein M1 is a single metal or a combination of metals, a>0, and b≥0, O standing for oxygen element, N standing for nitrogen element.

5. The array substrate of claim 3, wherein the first electrode comprises a first electrode part and a second electrode part electrically connected together; and
the first electrode part and the second electrode part are made of different materials.

6. The array substrate of claim 5, wherein the first electrode part comprises M1OₐN_{b}, wherein M1 is a single metal or a combination of metals, a>0, and b≥0, O standing for oxygen element, N standing for nitrogen element;
the second electrode part comprises a metallic material; and
the first electrode part, the second electrode, and the channel region are parts of a unitary structure.

7. The array substrate of claim 5, wherein the second electrode part is at least partially in the via; and
an orthographic projection of the second electrode part on the base substrate at least partially overlaps with an orthographic projection of the signal line on the base substrate, and at least partially overlaps with an orthographic projection of the first electrode part on the base substrate.

8. The array substrate of claim 7, wherein the orthographic projection of the first electrode part on the base substrate is non-overlapping with the orthographic projection of the signal line on the base substrate.

9. The array substrate of claim 7, wherein the orthographic projection of the first electrode part on the base substrate partially overlaps with the orthographic projection of the signal line on the base substrate.

10. The array substrate of claim 5, wherein the first electrode part at least partially extends into the second electrode part.

11. The array substrate of claim 5, further comprising:
an insulating layer on a side of the channel region, the first electrode part, and the second electrode away from the base substrate; and
a gate electrode on a side of the insulating layer away from the base substrate;
wherein the second electrode part and the gate electrode are in a same layer and comprise a same electrode material.

12. The array substrate of claim 1, wherein, in a cross-section along a plane perpendicular to the base substrate and perpendicular to a length direction along which the signal line extends, and intersecting the signal line and the via, surfaces of the signal line other than a bottom surface are exposed in the via; and
the bottom surface is a surface of the signal line in contact with the base substrate.

13. The array substrate of claim 12, wherein, in the cross-section, an upper surface of the signal line, and two lateral surfaces respectively connecting the upper surface to the bottom surface of the signal line, are fully covered by the first electrode.

14. The array substrate of claim 12, wherein, in the cross-section, an upper surface of only a portion of the signal line, and only one of two lateral surfaces respectively connecting the upper surface to the bottom surface of the signal line, are covered by the first electrode.

15. The array substrate of claim 1, wherein, in a cross-section along a plane perpendicular to the base substrate and perpendicular to a length direction along which the signal line extends, and intersecting the signal line and the via, at least a portion of an upper surface of the signal line, and at least one of two lateral surfaces respectively connecting the upper surface to a bottom surface of the signal line, are unexposed by the via; and
the bottom surface is a surface of the signal line in contact with the base substrate.

16. The array substrate of claim 15, wherein, in the cross-section, an upper surface of only a portion of the signal line, and at least one of two lateral surfaces respectively connecting the upper surface to the bottom surface of the signal line, are covered by the buffer layer.

17. The array substrate of claim 15, wherein, in the cross-section, an upper surface of only a portion of the signal line, and only one of two lateral surfaces respectively connecting the upper surface to the bottom surface of the signal line, are covered by the first electrode.

18. (canceled)

19. (canceled)

20. The array substrate of claim 1, wherein the active layer comprises a metal oxide material having a Hall mobility equal to or greater than 30 cm²/V·s.

21. The array substrate of claim 1, further comprising a light shield on the base substrate and a gate line on a side of the light shield away from the base substrate;
wherein the light shield is in a same layer as the signal line; and
a ratio between a line width of the gate line along an extension direction of the signal line and a line width of the light shield along the extension direction of the signal line is in a range of 0.3 to 0.9.

22. A display apparatus, comprising the array substrate of claim 1, and one or more integrated circuits connected to the array substrate.
